(19) United States
(12) Patent Application Publication
(10) Pub. No.: US 2025/0221200 A1
(43) Pub. Date: Jul. 3, 2025

(54) Transparent Display Apparatus

(71) Applicant: LG Display Co., Ltd., Seoul (KR)

(72) Inventor: Sunghee Park, Paju-si (KR)

(21) Appl. No.: 18/826,050

(22) Filed: Sep. 5, 2024

(30) Foreign Application Priority Data
Dec. 29, 2023 (KR) 10-2023-0197390

(51) Int. Cl. H10K 59/131

(52) U.S. Cl. CPC H10K 59/131

(57) ABSTRACT

A transparent display apparatus comprises a substrate including a non-transmissive area including a light emission area in which a light emitting element is disposed and a transmissive area, a plurality of data lines disposed in the non-transmissive area on the substrate and extended in a first direction, at least one gate line crossing the non-transmissive area and the transmissive area in a second direction crossing the first direction on the substrate, and at least one power line overlapped with at least a portion of the plurality of data lines with at least one insulating layer interposed therebetween on the substrate.

### CROSS-REFERENCE TO RELATED APPLICATION

This application claims priority to Republic of Korea Patent Application No. 10-2023-0197390 filed on Dec. 29, 2023, which is hereby incorporated by reference in its entirety.

### BACKGROUND

### Technical Field

The present disclosure relates to a transparent display apparatus.

### Description of the Related Art

With the advancement of the information age, the demand for a display apparatus for displaying an image has increased in various forms. Therefore, various types of display apparatuses such as a liquid crystal display (LCD) apparatus, an organic light emitting display (OLED) apparatus, a micro light emitting diode (LED) display apparatus and a quantum dot display (QD) apparatus have been recently used.

Recently, studies for a transparent display apparatus that displays an image for a user and allows the user to view objects or images, which are positioned at an opposite side thereof, by transmitting light are actively ongoing. The transparent display apparatus includes a display area, on which an image is displayed, and a non-display area, wherein the display area may include a transmissive area capable of transmitting external light and a non-transmissive area. The transparent display apparatus may have high light transmittance in the display area through the transmissive area.

### SUMMARY

The present disclosure has been made in view of the above problems and it is an object of the present disclosure to provide a transparent display apparatus that may have high light transmittance.

In addition to the objects of the present disclosure as mentioned above, additional objects and features of the present disclosure will be clearly understood by those skilled in the art from the following description of the present disclosure.

In accordance with an aspect of the present disclosure, the above and other objects may be accomplished by the provision of a transparent display apparatus comprising a substrate including a non-transmissive area including a light emission area in which a light emitting element is disposed and a transmissive area, a plurality of data lines disposed in the non-transmissive area on the substrate and extended in a first direction, at least one gate line crossing the non-transmissive area and the transmissive area in a second direction crossing the first direction on the substrate, and at least one power line overlapped with at least a portion of the plurality of data lines with at least one insulating layer interposed therebetween on the substrate.

A transparent display apparatus according to one or more embodiments of the present disclosure may include a substrate including a display area and a non-display area around the display area, the displayer area may include a plurality of light emission areas arranged in a first direction, a plurality of data lines in the plurality of light emission areas on the substrate, the plurality of data lines extending in the first direction, a plurality of gate lines on the substrate, the plurality of gate lines extending in a second direction that intersects the first direction, and a power line on the substrate, the power line overlapping with at least a portion of the plurality of data lines with an insulating layer interposed therebetween.

According to the embodiment of the present disclosure, the transparent display apparatus that may have high light transmittance may be provided.

The effects of the present disclosure are not limited to the aforesaid, but other effects not described herein will be clearly understood by those skilled in the art from descriptions below.

The details of the present disclosure described in technical problem, technical solution, and advantageous effects do not specify essential features of claims, and thus, the scope of claims is not limited by the details described in detailed description of the embodiments.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a view illustrating a transparent display apparatus according to the embodiment of the present disclosure;

FIG. 2 is a circuit view illustrating a subpixel of a transparent display apparatus according to the embodiment of the present disclosure;

FIG. 3 is a view illustrating an area A shown in FIG. 1 according to the embodiment of the present disclosure;

FIG. 4 is a view illustrating an area B shown in FIG. 3 according to the embodiment of the present disclosure;

FIG. 5 is a cross-sectional view taken along line I-I′ shown in FIG. 4 according to the embodiment of the present disclosure;

FIG. 6 is a view illustrating an area B shown in FIG. 3 according to one embodiment of the present disclosure;

FIG. 7 is a cross-sectional view taken along line II-II′ shown in FIG. 6 according to one embodiment of the present disclosure;

FIG. 8 is a cross-sectional view taken along line II-II′ shown in FIG. 6 according to another embodiment of the present disclosure;

FIG. 9 is a cross-sectional view taken along line II-II′ shown in FIG. 6 according to another embodiment of the present disclosure;

FIG. 10 is a cross-sectional view taken along line III-III′ shown in FIG. 6 according to another embodiment of the present disclosure;

FIG. 11 is a cross-sectional view taken along line III-III′ shown in FIG. 6 according to another embodiment of the present disclosure;

FIG. 12 is a plan view illustrating a power line and a data line according to one embodiment of the present disclosure;

FIG. 13 is a plan view illustrating a power line and a data line according to another embodiment of the present disclosure;

FIG. 14 is a plan view illustrating a power line and a data line according to another embodiment of the present disclosure;

FIG. 15 is a plan view illustrating a power line and a data line according to another embodiment of the present disclosure;

FIG. 16 is a plan view illustrating a power line and a data line according to another embodiment of the present disclosure;

FIG. 17 is a plan view illustrating a power line and a data line according to another embodiment of the present disclosure;

FIG. 18 is a cross-sectional view illustrating a transparent display apparatus according to one embodiment of the present disclosure; and

FIG. 19 is a cross-sectional view illustrating a transparent display apparatus according to another embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and/or convenience.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete, to assist those skilled in the art to understand the inventive concepts without limiting the protected scope of the present disclosure.

Shapes (e.g., sizes, lengths, widths, heights, thicknesses, locations, radii, diameters, and areas), sizes, ratios, angles, numbers, and the like disclosed herein, including those illustrated in the drawings are merely examples, and thus, the present disclosure is not limited to the illustrated details. Any implementation described herein as an “example” is not necessarily to be construed as preferred or advantageous over other implementations. It is, however, noted that the relative dimensions of the components illustrated in the drawings are part of the present disclosure.

When the term “comprise,” “have,” “include,” “contain,” “constitute,” “made of,” “formed of,” or the like is used with respect to one or more elements, one or more other elements may be added unless a term such as “only” or the like is used. The terms used in the present disclosure are merely used in order to describe example embodiments, and are not intended to limit the scope of the present disclosure. The terms of a singular form may include plural forms unless the context clearly indicates otherwise.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element is “contacts,” “overlaps,” or the like with another element, the element may not only directly contact, overlap, or the like with another element, but also indirectly contact, overlap, or the like with another element with one or more intervening elements disposed or interposed between the elements, unless otherwise specified.

The term “at least one” should be understood as including any and all combinations of one or more of the associated listed items. For example, “at least one among a first element, a second element and a third element” may include all combinations of two or more elements selected from the first, second and third elements as well as each element of the first, second and third elements.

Features of various embodiments of the present disclosure may be partially or entirety coupled to or combined with each other, may be technically associated with each other, and may be variously inter-operated, linked or driven together. The embodiments of the present disclosure may be implemented or carried out independently of each other, or may be implemented or carried out together in a co-dependent or related relationship. In one or more aspects, the components of each apparatus according to various embodiments of the present disclosure are operatively coupled and configured.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

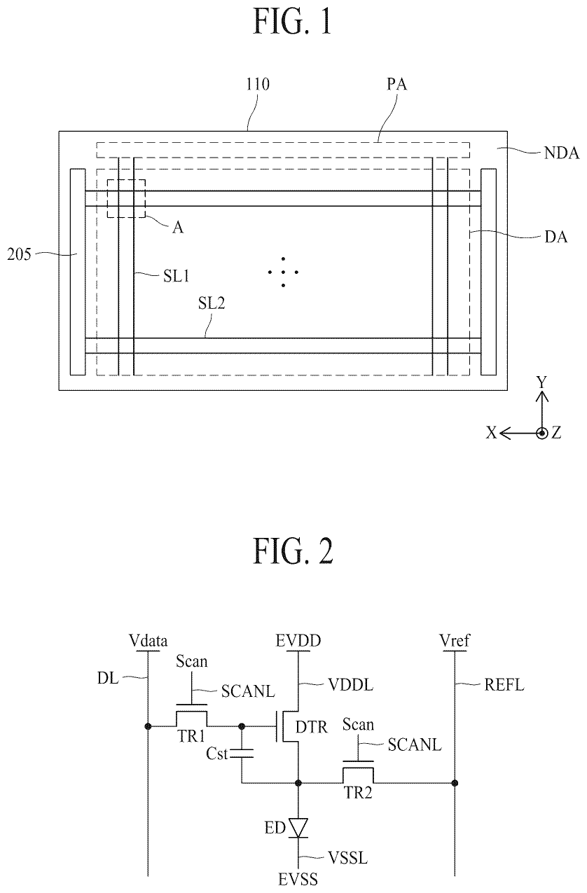

FIG. 1 is a view illustrating a transparent display apparatus according to the embodiment of the present disclosure. FIG. 2 is a circuit view illustrating a subpixel of a transparent display apparatus according to the embodiment of the present disclosure.

Hereinafter, X-axis represents a direction parallel with a scan line, Y-axis represents a direction parallel with a data line, and Z-axis represents a height direction of the transparent display apparatus.

Although the transparent display apparatus according to one embodiment of the present disclosure will be described to be implemented as an organic light emitting display (OLED), it may be also implemented as a liquid crystal display (LCD), a micro LED display, a quantum dot display (QD), etc.

Referring to FIGS. 1 and 2, the transparent display apparatus according to one embodiment of the present disclosure may include a transparent display panel 110 that includes a display area DA in which pixels are configured to display an image and a non-display area NDA in which an image is not displayed.

The display area DA of the transparent display panel 110 may include first signal lines SL1, second signal lines SL2 and pixels, and the non-display area NDA thereof may include a pad area PA in which pads are disposed and at least one gate driver 205.

The first signal lines SL1 may extend in a first direction (or Y-axis direction), and may cross the second signal lines SL2 in the display area DA. The second signal lines SL2 may extend in a second direction (or X-axis direction). The pixels may be disposed in an area where the first signal line SL1 and the second signal line SL2 cross each other, and may emit light of predetermined color to display an image.

The gate driver 205 may be connected to a scan line to supply a scan signal. The gate driver 205 may be implemented in a gate driver in panel (GIP) method or a tape automated bonding (TAB) method on the non-display area NDA outside one side or both sides of the display area DA of the transparent display panel 110.

A source drive integrated circuit, a circuit board or a timing controller, which is connected through a flexible circuit film, may be electrically connected to the pad area PA of the transparent display panel 110.

Referring to FIG. 2, each of the pixels includes a plurality of subpixels constituting a unit pixel, and each of the subpixels includes a circuit element having a 3T1C structure (three transistors and one capacitor) that includes a first switching transistor TR1, a second switching transistor TR2, a driving transistor DTR, and a capacitor Cst, and a light emitting element ED, but is not limited thereto. Each subpixel may further include a compensation circuit, and in this case, may have various structures such as 4T2C, 5T2C, 6T1C, 6T2C, 7T1C and 7T2C.

Each of the transistors DTR, TR1 and TR2 of each subpixel may include a gate electrode, a source electrode and a drain electrode. Since the source electrode and the drain electrode are not fixed and may be changed depending on a current direction and a voltage applied to the gate electrode, one of the source electrode and the drain electrode may be expressed as a first electrode and the other one may be expressed as a second electrode. The transistors DTR, TR1 and TR2 of each subpixel may use at least one of a polysilicon semiconductor, an amorphous silicon semiconductor or an oxide semiconductor. The transistors DTR, TR1 and TR2 may be P-type or N-type transistors, or P-type and N-type transistors may be used interchangeably.

The first switching transistor TR1 may serve to supply a data voltage Vdata supplied from a data line DL to the driving transistor DTR. For example, the first switching transistor TR1 may charge the capacitor Cst with the data voltage Vdata supplied from the data line DL. To this end, the gate electrode of the first switching transistor TR1 may be connected to a scan line SCANL (or a gate line), and a first electrode thereof may be connected to the data line DL. Also, a second electrode of the first switching transistor TR1 may be connected to one end of the capacitor Cst and the gate electrode of the driving transistor DTR.

The first switching transistor TR1 may be turned on in response to a scan signal Scan applied through the scan line SCANL (or the gate line). When the first switching transistor TR1 is turned on, the data voltage Vdata applied through the data line DL may be transferred to one end of the capacitor Cst.

The second switching transistor TR2 may serve to supply a reference voltage Vref supplied from a reference line REFL to the driving transistor DTR. For example, the gate electrode of the second switching transistor TR may be connected to the scan line SCANL (or the gate line), and a first electrode thereof may be connected to the reference line REFL. Also, the first electrode of the second switching transistor TR2 may be connected to a first electrode of the driving transistor DTR and the other end of the capacitor Cst.

The second switching transistor TR2 may be turned on in response to the scan signal Scan applied through the scan line SCANL (or the gate line). When the second switching transistor TR2 is turned on, the reference voltage Vref applied through the reference line REFL may be transmitted to the other end of the capacitor Cst. Also, the reference voltage Vref may be applied to the source electrode of the driving transistor DTR.

The capacitor Cst may serve to maintain the data voltage Vdata supplied to the driving transistor DTR for one frame. For example, a first electrode of the capacitor Cst may be connected to the gate electrode of the driving transistor DTR, and a second electrode thereof may be connected to the source electrode of the driving transistor DTR. The capacitor Cst may store a voltage corresponding to the data voltage Vdata transferred through the first switching transistor TR1, and may turn on the driving transistor DTR with the stored voltage.

The driving transistor DTR may generate a data current using a first power source EVDD supplied from a pixel power source line VDDL (or a first power source line) to supply the generated data current to an anode electrode of the light emitting element ED. For example, the gate electrode of the driving transistor DTR may be connected to one end of the capacitor Cst, and the first electrode thereof may be connected to the pixel power source line VDDL. Also, a second electrode of the driving transistor DTR may be connected to the anode electrode of the light emitting element ED.

The driving transistor DTR may be turned on depending on the data voltage charged in the capacitor Cst. When the driving transistor DTR is turned on, the first power source EVDD applied through the pixel power line VDDL may be transferred to the anode electrode of the light emitting element ED.

The light emitting element ED may include an anode electrode connected to the driving transistor DTR, a cathode electrode receiving a second power source EVSS from a common power line VSSL (or a second power line), and a light emitting layer between the anode electrode and the cathode electrode. The anode electrode is an independent electrode for each light emitting element, but the cathode electrode may be a common electrode shared by the entire light emitting elements. When a driving current is supplied from the driving transistor DTR, electrons from the cathode electrode may be injected into the light emitting layer and holes from the anode electrode may be injected into the light emitting layer, so that the light emitting element ED may allow fluorescent or phosphorescent materials to emit light through recombination of the electrons and the holes in the light emitting layer, thereby generating light of brightness proportional to a current value of the driving current.

The anode electrode of the light emitting element ED may be connected to the second electrode of the driving transistor DTR and the cathode electrode thereof may be connected to the common power line VSSL. The light emitting element ED may emit light in response to the driving current generated by the driving transistor DTR.

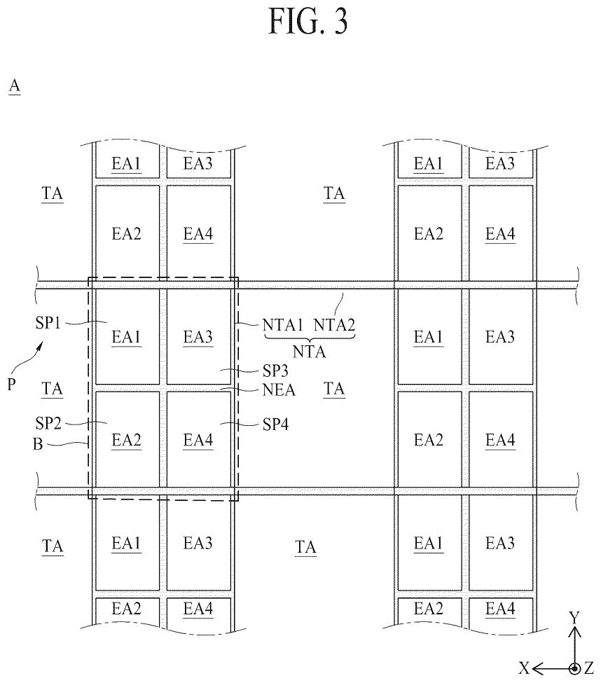

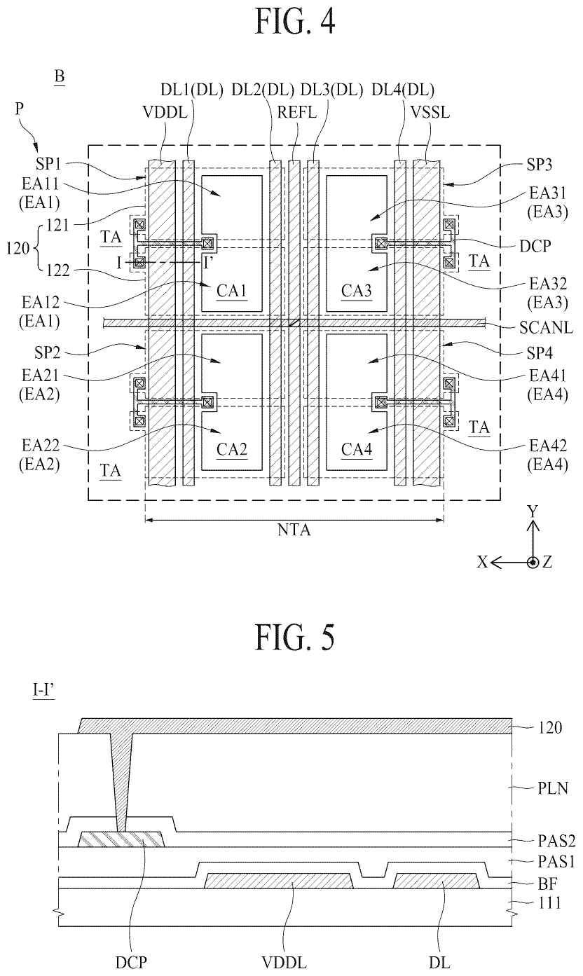

FIG. 3 is a view illustrating an area A shown in FIG. 1 according to the embodiment of the present disclosure. FIG. 4 is a view illustrating an area B shown in FIG. 3 according to the embodiment of the present disclosure. FIG. 5 is a cross-sectional view taken along line I-I′ shown in FIG. 4 according to the embodiment of the present disclosure.

Referring to FIGS. 3 to 5 in conjunction with FIGS. 1 and 2, the transparent display panel 110 according to the embodiment of the present disclosure may include a display area DA and a non-display area NDA. The display area DA may include a transmissive area TA and a non-transmissive area NTA. The transmissive area TA may be an area that transmits most of light incident from the outside, and the non-transmissive area NTA may be an area that does not transmit most of light incident from the outside. For example, the transmissive area TA may be an area having light transmittance greater than a %, and the non-transmissive area NTA may be an area having light transmittance smaller than B. In this case, a may be a value greater than B. A user may see an object or a background, which is positioned on a back surface (or a rear surface) of the transparent display panel 110, due to the transmissive areas TA.

The non-transmissive area NTA may include a first non-transmissive area NTA1, a second non-transmissive area NTA2 and pixels P.

The first non-transmissive area NTA1 extends in the first direction (or Y-axis direction) in the display area DA, and may be disposed to overlap at least a portion of light emission areas EA1, EA2, EA3 and EA4. A plurality of first non-transmissive areas NTA1 may be configured. The plurality of first non-transmissive areas NTA1 may extend in the first direction (or Y-axis direction), and may be disposed to be spaced apart from each other in the second direction (or X-axis direction). Two adjacent first non-transmissive areas NTA1 may be disposed to be spaced apart from each other with the transmissive area TA interposed therebetween. For example, the transmissive area TA may be disposed between the two adjacent first non-transmissive areas NTA1. The first signal lines SL1 extending in the first direction (or Y-axis direction) may be disposed in the first non-transmissive area NTA1. For example, the first signal lines SL1 may be disposed to overlap the first non-transmissive area NTA1.

The first signal lines SL1 may include at least one of the pixel power line VDDL (or the first power line), the common power line VSSL (or the second power line), the reference line REFL and data lines DL1, DL2, DL3 and DL4. For example, the first signal lines SL1 may further include a touch sensor line, but the embodiments of the present disclosure are not limited thereto.

The pixel power line VDDL (or the first power line) may supply the first power source EVDD to the driving transistor DTR of each of subpixels SP1, SP2, SP3 and SP4 provided in the display area DA.

The common power line VSSL (or the second power line) may supply the second power source EVSS to the cathode electrode of the subpixels SP1, SP2, SP3 and SP4 provided in the display area DA. In this case, the second power source EVSS may be a common power source supplied in common to the subpixels SP1, SP2, SP3 and SP4.

The reference line REFL may supply an initialization voltage (or a reference voltage) to the driving transistor DTR of each of the subpixels SP1, SP2, SP3 and SP4 provided in the display area DA. For example, the reference line REFL may be disposed between the plurality of data lines DL1, DL2, DL3 and DL4. For example, the reference line REFL may be disposed in the middle of the plurality of data lines DL1, DL2, DL3 and DL4.

Each of the data lines DL1, DL2, DL3 and DL4 may supply the data voltage Vdata to the subpixels SP1, SP2, SP3 and SP4. For example, the first data line DL1 may supply a first data voltage to a first driving transistor of the first subpixel SP1, the second data line DL2 may supply a second data voltage to a second driving transistor of the second subpixel SP2, the third data line DL3 may supply a third data voltage to a third driving transistor of the third subpixel SP3, and the fourth data line DLA may supply a fourth data voltage to a fourth driving transistor of the fourth subpixel SP4.

The second non-transmissive area NTA2 may extend from the display area DA in the second direction (or X-axis direction), and may be disposed to overlap at least a portion of the light emission areas EA1, EA2, EA3 and EA4. For example, the second non-transmissive area NTA2 may extend in the second direction (or X-axis direction) between two adjacent first non-transmissive areas NTA1. A plurality of second non-transmissive areas NTA2 may be configured. The plurality of second non-transmissive areas NTA2 may extend in the second direction (or X-side direction), and may be disposed to be spaced apart from each other in the first direction (or Y-axis direction). The two adjacent second non-transmissive areas NTA2 may be disposed to be spaced apart from each other with the transmissive area TA interposed therebetween. For example, the transmissive area TA may be disposed between two adjacent second non-transmissive areas NTA2. The second signal lines SL2 extended in the second direction (or X-axis direction) may be disposed in the second non-transmissive area NTA2. For example, the second signal lines SL2 may be disposed to overlap the second non-transmissive area NTA2.

The second signal lines SL2 may extend in the second direction (or X-axis direction), and may include the scan line SCANL (or the gate line). The scan line SCANL may supply the scan signal to the subpixels SP1, SP2, SP3 and SP4 of the pixel P.

The pixels P may be disposed in each crossing area where the first non-transmissive area NTA1 and the second non-transmissive area NTA2 cross each other, and may emit light to display an image. Each of the pixels P is disposed between adjacent transmissive areas TA, and the pixel P may include light emission areas EA1, EA2, EA3 and EA4 in which a light emitting element is disposed to emit light. The light emission areas EA1, EA2, EA3 and EA4 may correspond to areas, which emit light, in the pixel P. Since an area of the non-transmissive area NTA is small in the transparent display panel 110, the circuit element may be disposed to overlap the light emission areas EA1, EA2, EA3 and EA4. For example, the light emission areas EA1, EA2, EA3 and EA4 may at least partially overlap circuit areas CA1, CA2, CA3 and CA4 in which the circuit element is disposed. For example, the circuit areas CA1, CA2, CA3 and CA4 may include a first circuit area CA1 in which a circuit element connected to the first subpixel SP1 is disposed, a second circuit area CA2 in which a circuit element connected to the second subpixel SP2 is disposed, a third circuit area CA3 in which a circuit element connected to the third subpixel SP3 is disposed, and a fourth circuit area CA4 in which a circuit element connected to the fourth subpixel SP4 is disposed.

Each of the pixels P is provided in the first non-transmissive area NTA1, and may emit light to display an image. Each of the pixels P may include a first subpixel SP1, a second subpixel SP2, a third subpixel SP3 and a fourth subpixel SP4. The first subpixel SP1 may include a first light emission area EA1 emitting light of a first color, the second subpixel SP2 may include a second light emission area EA2 emitting light of a second color, the third subpixel SP3 may include a third light emission area EA3 emitting light of a third color, and the fourth subpixel SP4 may include a fourth light emission area EA4 emitting light of a fourth color. The first to fourth subpixels SP1, SP2, SP3 and SP4 may be disposed in a quad-type matrix along the first direction (or Y-axis direction) and the second direction (or X-axis direction). For example, the first subpixel SP1 and the second subpixel SP2 may be disposed to be adjacent to the pixel power line VDDL (or the first power line), and the third subpixel SP3 and the fourth subpixel SP4 may be disposed to be adjacent to the common power line VSSL (or the second power line). The scan line SCANL (or the gate line) may be disposed between the first subpixel SP1 and the second subpixel SP2 and between the third subpixel SP3 and the fourth subpixel SP4.

The first to fourth light emission areas EA1, EA2, EA3 and EA4 may emit light of different colors. For example, the first light emission area EA1 may emit green light, the second light emission area EA2 may emit blue light, the third light emission area EA3 may emit white light, and the fourth light emission area EA4 may emit red light, but the embodiments of the present disclosure are not limited thereto. For example, various modifications may be made in the arrangement order or arrangement form of each of the subpixels SP1, SP2, SP3 and SP4.

The transparent display panel 110 according to one embodiment of the present disclosure may include light emission areas in which the plurality of light emission areas EA1, EA2, EA3 and EA4 respectively included in the plurality of subpixels SP1, SP2, SP3 and SP4 are divided into a plurality of light emission areas. For example, each of the plurality of subpixels SP1, SP2, SP3 and SP4 may include a first divided electrode 121 and a second divided electrode 122 in which first electrodes 120 (or anode electrodes) of the light emitting element are spaced apart from each other. Each of the first divided electrode 121 and the second divided electrode 122 may correspond to the divided light emission area. For example, the first light emission area EA1 provided in the first subpixel SP1 may include a first divided light emission area EA11 and a second divided light emission area EA12, which correspond to the first divided electrode 121 and the second divided electrode 122. The second light emission area EA2 provided in the second subpixel SP2 may include a first divided light emission area EA21 and a second divided light emission area EA22, which correspond to the first divided electrode 121 and the second divided electrode 122. The third light emission area EA3 provided in the third subpixel SP3 may include a first divided light emission area EA31 and a second divided light emission area EA32, which correspond to the first divided electrode 121 and the second divided electrode 122. The fourth light emission area EA4 provided in the fourth subpixel SP4 may include a first divided light emission area EA41 and a second divided light emission area EA42, which correspond to the first divided electrode 121 and the second divided electrode 122.

The first divided electrode 121 and the second divided electrode 122 may be electrically connected to each other through a divided connection pattern DCP. The divided connection pattern DCP may serve to repair any one dark spot of the first divided electrode 121 and the second divided electrode 122. For example, the divided connection pattern DCP may electrically connect the first divided electrode 121 and the second divided electrode 122 to the circuit areas CA1, CA2, CA3 and CA4 of the subpixels SP1, SP2, SP3 and SP4. For example, the divided connection pattern DCP may be provided in the form of a “T” shape. One end of the divided connection pattern DCP may be branched to both sides to be electrically connected to the first divided electrode 121 and the second divided electrode 122, respectively, and the other end of the divided connection pattern DCP may be electrically connected to the circuit areas CA1, CA2, CA3 and CA4 of the subpixels SP1, SP2, SP3 and SP4. When particles occur in any one of the first divided electrode 121 and the second divided electrode 122, the divided connection pattern DCP may block the electrical connection between the divided electrode in which particles occur and the circuit areas CA1, CA2, CA3 and CA4, thereby serving to repair the divided electrodes so that only the divided electrode in which particles occur becomes a dark spot and the remaining divided electrode is normally operated.

Referring to FIG. 5 in conjunction with FIG. 4, the transparent display panel 110 according to the embodiment of the present disclosure may include first signal lines (e.g., a data line DL, a pixel power line VDDL, and a common power line VSSL) disposed in the non-transmissive area NTA and extended in the first direction (or Y-axis direction), a first electrode 120 (or an anode electrode) of a light emitting element, and a divided connection pattern DCP connected to the first divided electrode 121 and the second divided electrode 122 of the first electrode 120.

In detail, at least one of the data line DL, the pixel power line VDDL, the common power line VSSL or the reference line REFL of the first signal line may be disposed on a substrate 111. For example, as shown in FIG. 5, the data line DL and the pixel power line VDDL may be disposed on the substrate 111. The data line DL and the pixel power line VDDL may be formed of the same material on the same layer on the substrate 111. The data line DL and the pixel power line VDDL may be extended in parallel in the first direction (or Y-axis direction) in the non-transmissive area NTA. The data line DL and the pixel power line VDDL may be disposed to be spaced apart from each other on the same layer. For example, the data line DL may be disposed to be adjacent to the pixel power line VDDL. Also, the data line DL may be disposed to be adjacent to the common power line VSSL.

The data line DL and the pixel power line VDDL (or the common power line VSSL) may be disposed at a lowermost portion of the substrate 111. The data line DL and the pixel power line VDDL (or the common power line VSSL) may be formed of the same material on the same layer as a light shielding layer disposed on the substrate 111. For example, the light shielding layer may serve to shield external light incident on an active layer of a thin film transistor. The light shielding layer may be formed of a single layer or multi-layer made of any one of molybdenum (Mo), aluminum (Al), chromium (Cr), gold (Au), titanium (Ti), nickel (Ni), neodymium (Nd) and copper (Cu) or their alloy. For example, the first signal line made of the same material on the same layer as the light shielding layer on the substrate 111 may be at least one of the data line DL, the pixel power line VDDL, the common power line VSSL or the reference line REFL, but the embodiments of the present disclosure are not limited thereto.

A buffer layer BF may be disposed on the substrate 111 on which the data line DL, the pixel power line VDDL (or the common power line VSSL) and the light shielding layer are disposed. The buffer layer BF is to protect the thin film transistor from moisture permeated through the substrate 111 that may be vulnerable to moisture permeation, and may be formed of a single layer or multi-layer containing an inorganic insulating material such as silicon oxide (SiOₓ), silicon nitride (SiNₓ) and aluminum oxide (Al₂O₃).

At least one insulating layer, a thin film transistor and at least one signal line may be disposed on the buffer layer BF. For example, as shown in FIG. 5, a first passivation layer PAS1 may be disposed on the buffer layer BF. A second passivation layer PAS2 may be disposed on the first passivation layer PAS1. The first passivation layer PAS1 and the second passivation layer PAS2 may be formed of a single layer or multi-layer containing an inorganic insulating material such as silicon oxide (SiOₓ), silicon nitride (SiNₓ) and aluminum oxide (Al₂O₃).

The divided connection pattern DCP may be disposed on the first passivation layer PAS1. For example, the divided connection pattern DCP may be disposed between the first passivation layer PAS1 and the second passivation layer PAS2. The divided connection pattern DCP may include a transparent or opaque conductive material. For example, the divided connection pattern DCP may be a single layer containing at least one of molybdenum (Mo), copper (Cu), molytitanium (MoTi) or indium tin oxide (ITO) or a multi-layer containing at least two of them, but the embodiments of the present disclosure are not limited thereto.

A planarization layer PLN for planarizing a step difference caused by a thin film transistor and a plurality of signal lines may be disposed on the second passivation layer PAS2. The planarization layer PLN may be formed of an organic material such as an acrylic resin, an epoxy resin, a phenolic resin, a polyamide resin and a polyimide resin.

A first electrode, a light emitting layer and a second electrode, which constitute a light emitting element, may be disposed on the planarization layer PLN. For example, as shown in FIG. 5, the first electrode 120 (or the anode electrode) may be disposed on the planarization layer PLN. The first electrode 120 may be electrically connected to the divided connection pattern DCP through a contact hole passing through at least one insulating layer interposed therebetween. For example, the first electrode 120 may be electrically connected to the divided connection pattern DCP through a contact hole passing through the planarization layer PLN and the second passivation layer PAS2. According to the embodiment of the present disclosure, the first electrode 120 may include a first divided electrode 121 and a second divided electrode 122, which are spaced apart from each other, and the first divided electrode 121 and the second divided electrode 122 of the first electrode 120 may be electrically connected to the divided connection pattern DCP. The divided connection pattern DCP may serve to repair a dark spot of any one of the first divided electrode 121 and the second divided electrode 122.

The transparent display panel 110 according to one embodiment of the present disclosure includes a non-transmissive area NTA in which the light emitting element is disposed and a transmissive area TA through which light may transmit. The first electrode 120 of the light emitting element is divided into the first divided electrode 121 and the second divided electrode 122, the first divided electrode 121 and the second divided electrode 122 are electrically connected to each other through the divided connection pattern DCP, and the dark spot of any one of the first divided electrode 121 and the second divided electrode 122 may be repaired by a repair process for the divided connection pattern DCP, whereby the transparent display panel 110 may be implemented or realized. In the transparent display panel 110 according to the embodiment of the present disclosure, the area of the transmissive area TA may be a major factor in increasing light transmittance. Therefore, the inventors of the present disclosure invented a transparent display apparatus having a new structure that may enlarge the transmissive area TA of the transparent display panel 110 through various studies and experiments.

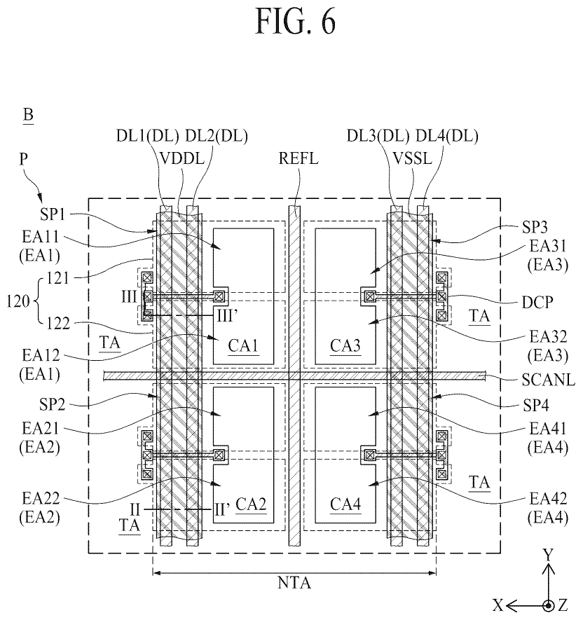

Hereinafter, a transparent display apparatus according to another embodiment of the present disclosure, which may improve light transmittance by enlarging a transmissive area, will be described in more detail with reference to FIGS. 6 to 18.

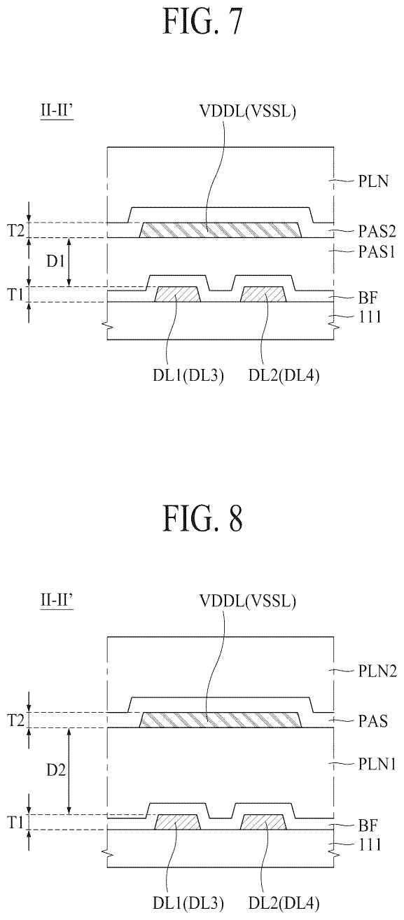

FIG. 6 is a view illustrating an area B shown in FIG. 3 according to one embodiment of the present disclosure. FIG. 7 is a cross-sectional view taken along line II-II′ shown in FIG. 6 according to one embodiment of the present disclosure. The data line DL, the pixel power line VDDL, the common power line VSSL and the divided connection pattern DCP in the transparent display panel 110 described with reference to FIGS. 1 to 5 are modified in FIGS. 6 and 7. Therefore, in the following description, the same reference numerals will be given to the other same elements except for the modified elements, and their redundant description will be omitted or briefly described.

Referring to FIGS. 6 and 7 in conjunction with FIGS. 1 to 3, the transparent display panel 110 according to another embodiment of the present disclosure may include a display area DA and a non-display area NDA, and the display area DA may include a transmissive area TA and a non-transmissive area NTA.

The transparent display panel 110 according to another embodiment of the present disclosure may include first signal lines SL1 (e.g., a data line DL, a pixel power line VDDL, and a common power line VSSL) disposed in the non-transmissive area NTA and extended in a first direction (or Y-axis direction), a second signal line SL2 (e.g., a scan line SCANL) disposed in the non-transmissive area NTA and the transmissive area TA, crossing the transmissive area TA in a second direction (e.g., X-axis direction), a first electrode 120 of a light emitting element, which includes a first divided electrode 121 and a second divided electrode 122, and a divided connection pattern DCP connected to the first divided electrode 121 and the second divided electrode 122 of the first electrode 120.

The first signal lines SL1 may include at least one of the pixel power line VDDL (or the first power line), the common power line VSSL (or the second power line), the reference line REFL or the data lines DL1, DL2, DL3 and DL4. The second signal lines SL2 may include a scan line SCANL (or a gate line). For example, the first signal lines SL1 may further include a touch sensor line, but the embodiments of the present disclosure are not limited thereto.

The pixel power line VDDL (or the first power line) may supply the first power source EVDD to the driving transistor DTR of each of the subpixels SP1, SP2, SP3 and SP4 provided in the display area DA. For example, the pixel power line VDDL may be disposed at one side (or left side) of the plurality of subpixels SP1, SP2, SP3 and SP4 in the second direction (or X-axis direction). The first subpixel SP1 and the second subpixel SP2 of the plurality of subpixels SP1, SP2, SP3 and SP4 may be disposed to be adjacent to the pixel power line VDDL.

The pixel power line VDDL may overlap at least a portion of the plurality of data lines DL1, DL2, DL3 and DL4 with at least one insulating layer interposed therebetween. The pixel power line VDDL may be extended in parallel with the plurality of data lines DL1, DL2, DL3 and DL4 in the first direction (or Y-axis direction). For example, the pixel power line VDDL may be disposed to overlap the first data line DL1 and the second data line DL2 of the plurality of data lines DL1, DL2, DL3 and DL4. The pixel power line VDDL may have a width equal to or greater than widths of the first data line DL1 and the second data line DL2. For example, the pixel power line VDDL may be configured to have a width greater than a combined width of the first data line DL1 and the second data line DL2.

The common power line VSSL (or the second power line) may supply the second power source EVSS to the cathode electrode of the subpixels SP1, SP2, SP3 and SP4 provided in the display area DA. In this case, the second power source EVSS may be a common power source supplied in common to the subpixels SP1, SP2, SP3 and SP4. For example, the common power line VSSL may be disposed at the other side (or the right side) of the plurality of subpixels SP1, SP2, SP3 and SP4 in the second direction (or X-axis direction). The third subpixel SP3 and the fourth subpixel SP4 of the plurality of subpixels SP1, SP2, SP3 and SP4 may be disposed to be adjacent to the common power line VSSL.

The common power line VSSL may overlap at least a portion of the plurality of data lines DL1, DL2, DL3 and DL4 with at least one insulating layer interposed therebetween. The common power line VSSL may be extended in parallel with the plurality of data lines DL1, DL2, DL3 and DL4 in the first direction (or Y-axis direction). For example, the common power line VSSL may be disposed to overlap the third data line DL3 and the fourth data line DL4 of the plurality of data lines DL1, DL2, DL3 and DL4. The common power line VSSL may have a width equal to or greater than widths of the third data line DL3 and the fourth data line DL4. For example, the common power line VSSL may be configured to have a width greater than a combined width of the third data line DL3 and the fourth data line DL4.

The reference line REFL may supply an initialization voltage (or a reference voltage) to the driving transistor DTR of each of the subpixels SP1, SP2, SP3 and SP4 provided in the display area DA. For example, the reference line REFL may be disposed between the subpixels SP1, SP2, SP3 and SP4. The reference line REFL may be disposed in the middle of the subpixels SP1, SP2, SP3 and SP4. For example, the reference line REFL may be extended in the first direction (or Y-axis direction) between the first subpixel SP1 and the third subpixel SP3 and between the second subpixel SP2 and the fourth subpixel SP4.

Each of the data lines DL1, DL2, DL3 and DL4 may supply the data voltage Vdata to the subpixels SP1, SP2, SP3 and SP4. For example, the first data line DL1 and the second data line DL2 of the data lines DL1, DL2, DL3 and DL4 may be disposed at one side (or left side) of the plurality of subpixels SP1, SP2, SP3 and SP4 in the second direction (or X-axis direction), and the first data line DL1 may supply a first data voltage to the first driving transistor of the first subpixel SP1 and the second data line DL2 may supply a second data voltage to the second driving transistor of the second subpixel SP2. The third data line DL3 and the fourth data line DL4 of the data lines DL1, DL2, DL3 and DL4 may be disposed at the other side (or right side) of the plurality of subpixels SP1, SP2, SP3 and SP4 in the second direction (or X-axis direction), and the third data line DL3 may supply a third data voltage to the third driving transistor of the third subpixel SP3 and the fourth data line DL4 may supply a fourth data voltage to the fourth driving transistor of the fourth subpixel SP4.

The first data line DL1 and the second data line DL2 of the data lines DL1, DL2, DL3 and DL4 may overlap the pixel power line VDDL (or the first power line). The first data line DL1 and the second data line DL2 may be spaced apart from the pixel power line VDDL in a vertical direction (or Z-axis direction or thickness direction) with at least one insulating layer interposed therebetween. The first data line DL1 and the second data line DL2 may be spaced apart from each other in a width direction (or X-axis direction) of the pixel power line VDDL. For example, a spaced distance between the first data line DL1 and the second data line DL2 may be equal to or longer than the width of each of the first data line DL1 and the second data line DL2.

The third data line DL3 and the fourth data line DL4 of the data lines DL1, DL2, DL3 and DL4 may overlap the common power line VSSL (or the second power line). The third data line DL3 and the fourth data line DL4 may be spaced apart from the common power line VSSL in the vertical direction (or Z-axis direction or thickness direction) with at least one insulating layer interposed therebetween. The third data line DL3 and the fourth data line DL4 may be spaced apart from each other in a width direction (or X-axis direction) of the common power line VSSL. For example, a spaced distance between the third data line DL3 and the fourth data line DL4 may be equal to or longer than the width of each of the third data line DL3 and the fourth data line DL4.

The scan line SCANL (or the gate line) may supply a scan signal to each of the subpixels SP1, SP2, SP3 and SP4 provided in the display area DA. The scan line SCANL may be disposed in the non-transmissive area NTA and the transmissive area TA, and may be disposed across the transmissive area TA in the second direction (or X-axis direction). The scan line SCANL may be disposed between the first subpixel SP1 and the second subpixel SP2 in the first direction (or Y-axis direction) and between the third subpixel SP3 and the fourth subpixel SP4.

The divided connection pattern DCP according to another embodiment of the present disclosure may serve to repair the dark spot of any one of the first divided electrode 121 and the second divided electrode 122. For example, the divided connection pattern DCP may electrically connect the first divided electrode 121 and the second divided electrode 122 to the circuit areas CA1, CA2, CA3 and CA4 of the subpixels SP1, SP2, SP3 and SP4. For example, the divided connection pattern DCP may be provided in the form of a “1” shape. The divided connection pattern DCP is branched to one end and the other end based on a central portion to be electrically connected to each of the first divided electrode 121 and the second divided electrode 122, and the central portion of the divided connection pattern DCP may be electrically connected to the circuit areas CA1, CA2, CA3 and CA4 of the subpixels SP1, SP2, SP3 and SP4 through a connection pattern disposed on a layer different from the divided connection pattern DCP. The divided connection pattern DCP may be formed of the same material on the same layer as the pixel power line VDDL and the common power line VSSL. When particles occur in any one of the first divided electrode 121 and the second divided electrode 122, the divided connection pattern DCP may block the electrical connection between the divided electrode in which particles occur and the circuit areas CA1, CA2, CA3 and CA4, thereby serving to repair the divided electrodes so that only the divided electrode in which particles occur becomes a dark spot and the remaining divided electrode is normally operated.

Referring to FIG. 7 in conjunction with FIG. 6, the data lines DL1, DL2, DL3 and DL4 may be disposed on a substrate 111. For example, as shown in FIG. 6, on the substrate 111, the first data line DL1 and the second data line DL2 of the data lines DL1, DL2, DL3 and DL4 may be disposed to be adjacent to each other, and the third data line DL3 and the fourth data line DL4 may be disposed to be adjacent to each other.

The data lines DL1, DL2, DL3 and DL4 may be disposed at a lowermost end of the substrate 111. The data lines DL1, DL2, DL3 and DL4 may be formed of the same material on the same layer as the light shielding layer disposed on the substrate 111. For example, the light shielding layer may serve to shield external light incident on an active layer of a thin film transistor. The light shielding layer may be formed of a single layer or multi-layer made of any one of molybdenum (Mo), aluminum (Al), chromium (Cr), gold (Au), titanium (Ti), nickel (Ni), neodymium (Nd) and copper (Cu) or their alloy. For example, the first signal line made of the same material on the same layer as the light shielding layer on the substrate 111 may be at least one of the data lines DL1, DL2, DL3 and DL4 or the reference line REFL, but the embodiments of the present disclosure are not limited thereto.

A buffer layer BF may be disposed on the substrate 111 on which the data lines DL1, DL2, DL3 and DL4 and the light shielding layer are disposed. The buffer layer BF is to protect the thin film transistor from moisture permeated through the substrate 111 that may be vulnerable to moisture permeation, and may be formed of a single layer or multi-layer containing an inorganic insulating material such as silicon oxide (SiOₓ), silicon nitride (SiNₓ) and aluminum oxide (Al₂O₃).

At least one insulating layer, a thin film transistor and at least one signal line may be disposed on the buffer layer BF. For example, as shown in FIG. 6, a first passivation layer PAS1 may be disposed on the buffer layer BF. A second passivation layer PAS2 may be disposed on the first passivation layer PAS1. The first passivation layer PAS1 and the second passivation layer PAS2 may be formed of a single layer or multi-layer containing an inorganic insulating material such as silicon oxide (SiOₓ), silicon nitride (SiNₓ) and aluminum oxide (Al₂O₃).

The pixel power line VDDL (or the first power line) and the common power line VSSL (or the second power line) may be disposed on the first passivation layer PAS1. The pixel power line VDDL and the common power line VSSL may be disposed between the first passivation layer PAS1 and the second passivation layer PAS2. The pixel power line VDDL and the common power line VSSL may be a single layer containing at least one of molybdenum (Mo), copper (Cu), molytitanium (MoTi) or indium tin oxide (ITO) or a multi-layer containing at least two of them, but the embodiments of the present disclosure are not limited thereto.

The pixel power line VDDL and the common power line VSSL may overlap at least a portion of the plurality of data lines DL1, DL2, DL3 and DL4, with the first passivation layer PAS1 and the buffer layer BF, which are interposed therebetween. For example, the pixel power line VDDL may overlap the first data line DL1 and the second data line DL2, with the first passivation layer PAS1 and the buffer layer BF, which are interposed therebetween. The common power line VSSL may overlap the third data line DL3 and the fourth data line DL4, with the first passivation layer PAS1 and the buffer layer BF, which are interposed therebetween.

The pixel power line VDDL and the common power line VSSL may have thicknesses equal to or different from those of the plurality of data lines DL1, DL2, DL3 and DL4. For example, the plurality of data lines DL1, DL2, DL3 and DL4 may be configured to have a first thickness T1, and the pixel power line VDDL and the common power line VSSL may be configured to have a second thickness T2. The first thickness T1 may be equal to or different from the second thickness T2.

The pixel power line VDDL and the common power line VSSL may be spaced apart from the plurality of data lines DL1, DL2, DL3 and DL4 as much as a first distance D1 in the vertical direction (or Z-axis direction or thickness direction) by the first passivation layer PAS1 and the buffer layer BF. The first passivation layer PAS1 and the buffer layer BF may have a thickness equal to or greater than the first thickness T1 of the plurality of data lines DL1, DL2, DL3 and DL4. For example, the first passivation layer PAS1 and the buffer layer BF may have a thickness equal to or greater than a multiple of the first thickness T1 of the plurality of data lines DL1, DL2, DL3 and DL4. Therefore, the first distance D1 between the pixel power line VDDL and the common power line VSSL and the plurality of data lines DL1, DL2, DL3 and DL4 may be equal to or longer than a multiple of the first thickness T1 of the plurality of data lines DL1, DL2, DL3 and DL4, and may be configured to reduce the influence of parasitic capacitance.

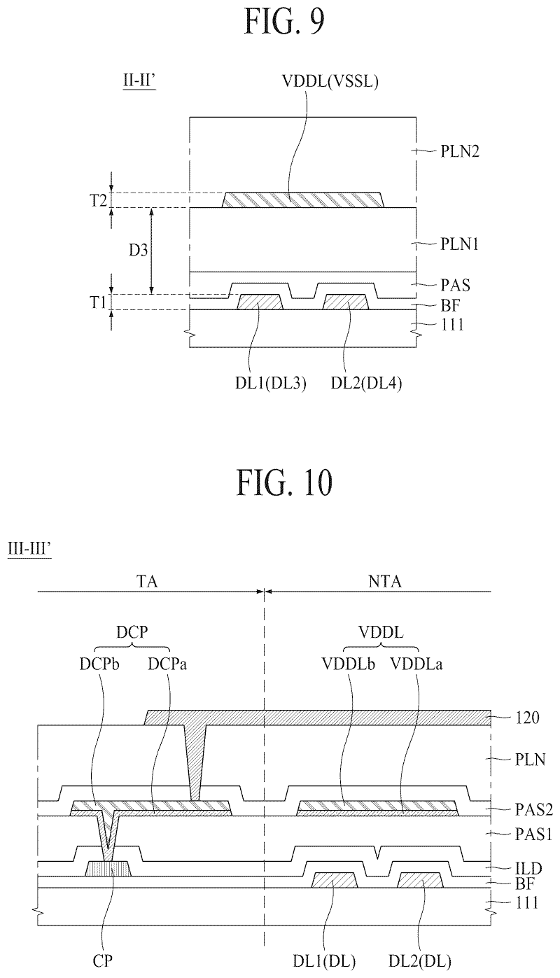

FIGS. 8 and 9 are other cross-sectional views taken along line II-II′ shown in FIG. 6 according to another embodiment of the present disclosure. At least one insulating layer shown in FIG. 7 is modified in FIGS. 8 and 9. Therefore, in the following description, the same reference numerals will be given to the other same elements except for the modified element, and their redundant description will be omitted or briefly described.

Referring to FIG. 8, a first planarization layer PLN1 may be disposed on the buffer layer BF. The first planarization layer PLN1 is to planarize a step difference caused by a thin film transistor and a plurality of signal lines, which are interposed between the first planarization layer PLN and the substrate 111, and may be formed of an organic material such as an acrylic resin, an epoxy resin, a phenolic resin, a polyamide resin and a polyimide resin.

The pixel power line VDDL (or the first power line) and the common power line VSSL (or the second power line) may be disposed on the first planarization layer PLN1. A passivation layer PAS and a second planarization layer PLN2 may be disposed on the first planarization layer PLN1 on which the pixel power line VDDL and the common power line VSSL are disposed. The passivation layer PAS may be formed of a single layer or multi-layer containing an inorganic insulating material such as silicon oxide (SiOₓ), silicon nitride (SiNₓ) and aluminum oxide (Al₂O₃). The second planarization layer PLN2 may be formed of the same material as that of the first planarization layer PLN1. The pixel power line VDDL and the common power line VSSL may be disposed between the first planarization layer PLN1 and the passivation layer PAS.

The pixel power line VDDL and the common power line VSSL may overlap at least a portion of the plurality of data lines DL1, DL2, DL3 and DL4, with the first planarization layer PLN1 and the buffer layer BF, which are interposed therebetween. For example, the pixel power line VDDL may overlap the first data line DL1 and the second data line DL2, with the first planarization layer PLN1 and the buffer layer BF, which are interposed therebetween. The common power line VSSL may overlap the third data line DL3 and the fourth data line DL4, with the first planarization layer PLN1 and the buffer layer BF, which are interposed therebetween.

The pixel power line VDDL and the common power line VSSL may be spaced apart from the plurality of data lines DL1, DL2, DL3 and DL4 as much as a second distance D2 in the vertical direction (or Z-axis direction or thickness direction) by the first planarization layer PLN1 and the buffer layer BF. The first planarization layer PLN1 and the buffer layer BF may have a thickness equal to or greater than the first thickness T1 of the plurality of data lines DL1, DL2, DL3 and DL4. For example, the first planarization layer PLN1 and the buffer layer BF may have a thickness equal to or greater than a multiple of the first thickness T1 of the plurality of data lines DL1, DL2, DL3 and DL4. For example, the second distance D2 may be equal to or longer than the first distance D1 shown in FIG. 7. Therefore, the second distance D2 between the pixel power line VDDL and the common power line VSSL and the plurality of data lines DL1, DL2, DL3 and DL4 may be equal to or longer than a multiple of the first thickness T1 of the plurality of data lines DL1, DL2, DL3 and DL4, and may be configured to further reduce the influence of parasitic capacitance.

Referring to FIG. 9, the passivation layer PAS may be disposed on the buffer layer BF. The passivation layer PAS may be formed of a single layer or multi-layer containing an inorganic insulating material such as silicon oxide (SiOₓ), silicon nitride (SiNₓ) and aluminum oxide (Al₂O₃).

The first planarization layer PLN1 may be disposed on the buffer layer BF. The first planarization layer PLN1 is to planarize a step difference caused by a thin film transistor and a plurality of signal lines, which are interposed between the first planarization layer PLN1 and the substrate 111, and may be formed of an organic material such as an acrylic resin, an epoxy resin, a phenolic resin, a polyamide resin and a polyimide resin.

The pixel power line VDDL (or the first power line) and the common power line VSSL (or the second power line) may be disposed on the first planarization layer PLN1. The second planarization layer PLN2 may be disposed on the first planarization layer PLN1 on which the pixel power line VDDL and the common power line VSSL are disposed. The second planarization layer PLN2 may be formed of the same material as that of the first planarization layer PLN1. The pixel power line VDDL and the common power line VSSL may be disposed between the first planarization layer PLN1 and the second planarization layer PLN2.

The pixel power line VDDL and the common power line VSSL may overlap at least a portion of the plurality of data lines DL1, DL2, DL3 and DL4, with the first planarization layer PLN1, the passivation layer and the buffer layer BF, which are interposed therebetween. For example, the pixel power line VDDL may overlap the first data line DL1 and the second data line DL2, with the first planarization layer PLN1, the passivation layer PAS and the buffer layer BF, which are interposed therebetween. The common power line VSSL may overlap the third data line DL3 and the fourth data line DL4, with the first planarization layer PLN1, the passivation layer PAS and the buffer layer BF, which are interposed therebetween.

The pixel power line VDDL and the common power line VSSL may be spaced apart from the plurality of data lines DL1, DL2, DL3 and DL4 as much as a third distance D3 in the vertical direction (or Z-axis direction or thickness direction) by the first planarization layer PLN1, the passivation layer PAS and the buffer layer BF. The first planarization layer PLN1, the passivation layer PAS and the buffer layer BF may have a thickness equal to or greater than the first thickness T1 of the plurality of data lines DL1, DL2, DL3 and DL4. For example, the first planarization layer PLN1, the passivation layer PAS and the buffer layer BF may have a thickness equal to or greater than a multiple of the first thickness T1 of the plurality of data lines DL1, DL2, DL3 and DL4. For example, the third distance D3 may be equal to or longer than the first distance D1 or the second distance D2, which is shown in FIGS. 7 and 8. Therefore, the third distance D3 between the pixel power line VDDL and the common power line VSSL and the plurality of data lines DL1, DL2, DL3 and DL4 may be equal to or longer than a multiple of the first thickness T1 of the plurality of data lines DL1, DL2, DL3 and DL4, and may be configured to further reduce the influence of parasitic capacitance.

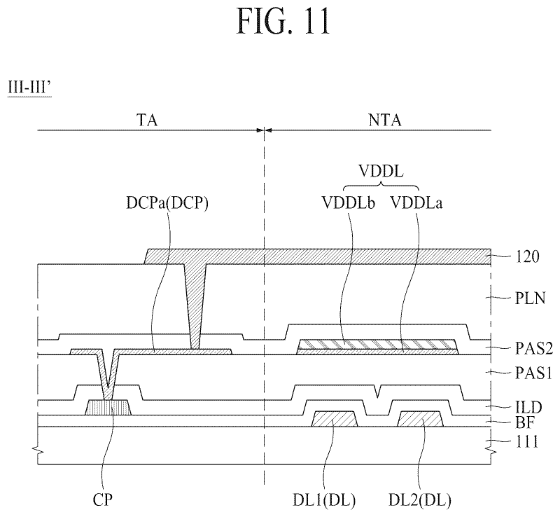

FIG. 10 is a cross-sectional view taken along line III-III′ shown in FIG. 6 according to another embodiment of the present disclosure. The data line DL, the pixel power line VDDL, the common power line VSSL and the divided connection pattern DCP in the transparent display panel 110 described with reference to FIGS. 1 to 5 are modified in FIG. 10. Therefore, in the following description, the same reference numerals will be given to the other same elements except for the modified elements, and their redundant description will be omitted or briefly described.

Referring to FIG. 10 in conjunction with FIG. 6, data lines DL may be disposed on the substrate 111. For example, among the data lines DL, the first data line DL1 and the second data line DL2 may be disposed to be adjacent to each other, and the third data line DL3 and the fourth data line DL4 may be disposed to be adjacent to each other.

The data line DL may be disposed at the lowermost end of the substrate 111, and may be formed of the same material on the same layer as the light shielding layer on the substrate 111.

A buffer layer BF may be disposed on the substrate 111 on which the data line DL and the light shielding layer are disposed.

At least one insulating layer, a thin film transistor and at least one signal line may be disposed on the buffer layer BF. For example, as shown in FIG. 10, a connection pattern CP may be disposed on the buffer layer BF. The connection pattern CP may electrically connect a divided connection pattern DCP to the circuit areas CA1, CA2, CA3 and CA4 of the subpixels SP1, SP2, SP3 and SP4. The divided connection pattern DCP may be electrically connected to the circuit areas CA1, CA2, CA3 and CA4 of the subpixels SP1, SP2, SP3 and SP4 through the connection pattern CP. For example, the connection pattern CP may be provided in the form of a “1” shape. The connection pattern CP may be extended to be perpendicular to the divided connection pattern DCP. For example, the divided connection pattern DCP may be configured to be extended in a first direction (or Y-axis direction), and the connection pattern CP may be configured to be extended in a second direction (or X-axis direction) crossing the first direction. The connection pattern CP may be disposed to overlap a central portion of the divided connection pattern DCP. The connection pattern CP may be connected to the central portion of the divided connection pattern DCP. The connection pattern CP may be disposed to cross the data line DL, the pixel power line VDDL and the common power line VSSL. The connection pattern CP may be disposed on a layer different from the data line DL, the pixel power line VDDL and the common power line VSSL. The connection pattern CP may be disposed on a different layer between the pixel power line VDDL and the common power line VSSL and the data line DL. For example, the connection pattern CP may be formed of the same material on the same layer as the gate electrode of the thin film transistor disposed on the buffer layer BF or the scan line SCANL, but the embodiments of the present disclosure are not limited thereto.

An interlayer insulating layer ILD may be disposed on the buffer layer BF on which the connection pattern CP is disposed. For example, the interlayer insulating layer ILD may be disposed between the gate electrode and the source/drain electrode of the thin film transistor. The interlayer insulating layer ILD may be formed of a single layer or multi-layer containing an inorganic insulating material such as silicon oxide (SiOₓ), silicon nitride (SiNₓ) and aluminum oxide (Al₂O₃).

A first passivation layer PAS1 may be disposed on the interlayer insulating layer ILD. A second passivation layer PAS2 may be disposed on the first passivation layer PAS1. The first passivation layer PAS1 and the second passivation layer PAS2 may be formed of a single layer or multi-layer containing an inorganic insulating material such as silicon oxide (SiOₓ), silicon nitride (SiNₓ) and aluminum oxide (Al₂O₃).

A pixel power line VDDL (or a first power line) and a common power line VSSL (or a second power line) may be disposed on the first passivation layer PAS1. The pixel power line VDDL and the common power line VSSL may be disposed between the first passivation layer PAS1 and the second passivation layer PAS2. The divided connection pattern DCP may be disposed on the same layer as the pixel power line VDDL and the common power line VSSL on the first passivation layer PAS1. The divided connection pattern DCP may be disposed in the transmissive area TA. The divided connection pattern DCP may be disposed between the first passivation layer PAS1 and the second passivation layer PAS2.

The divided connection pattern DCP may serve to repair a dark spot of any one of the first divided electrode 121 and the second divided electrode 122. For example, the divided connection pattern DCP may electrically connect the first divided electrode 121 and the second divided electrode 122 to the circuit areas CA1, CA2, CA3 and CA4 of the subpixels SP1, SP2, SP3 and SP4 through the connection pattern CP. For example, the divided connection pattern DCP may be provided in the form of a “1” shape. The divided connection pattern DCP is branched to one end and the other end based on the central portion to be electrically connected to each of the first divided electrode 121 and the second divided electrode 122, and the central portion of the divided connection pattern DCP may be electrically connected to the circuit areas CA1, CA2, CA3 and CA4 of the subpixels SP1, SP2, SP3 and SP4 through the connection pattern CP disposed on a layer different from the divided connection pattern DCP. The divided connection pattern DCP may be electrically connected to the connection pattern CP through a contact hole passing through the first passivation layer PAS1 and the interlayer insulating layer ILD.

The pixel power line VDDL, the common power line VSSL and the divided connection pattern DCP may be a single layer containing at least one of molybdenum (Mo), copper (Cu), molytitanium (MoTi) and indium tin oxide (ITO) or may be a multi-layer containing at least two of them. For example, the pixel power line VDDL, the common power line VSSL and the divided connection pattern DCP may have a multi-layered structure that includes a transparent metal layer and an opaque metal layer. For example, the pixel power line VDDL may include a first layer VDDLa made of a transparent metal layer and a second layer VDDLb stacked on the first layer VDDLa and made of an opaque metal layer. The divided connection pattern DCP may include a first layer DCPa made of a transparent metal layer and a second layer VDDLb stacked on the first layer DCPb and made of an opaque metal layer. For example, the first layers VDDla and DCPa of the pixel power line VDDL and the divided connection pattern DCP may be made of indium tin oxide (ITO), but the embodiments of the present disclosure are not limited thereto. The second layers VDDLb and DCPb of the pixel power line VDDL and the divided connection pattern DCP may be a single layer containing at least one of molybdenum (Mo), copper (Cu) or molytitanium (MoTi) or a multi-layer of at least two of them, but the embodiments of the present disclosure are not limited thereto. Although only the pixel power line VDDL is shown in FIG. 10, the common power line VSSL may be also configured to be substantially the same as the pixel power line VDDL.

A planarization layer PLN for planarizing a step difference caused by a thin film transistor and a plurality of signal lines may be disposed on the second passivation layer PAS2. The planarization layer PLN may be formed of an organic material such as an acrylic resin, an epoxy resin, a phenolic resin, a polyamide resin and a polyimide resin.

A first electrode, a light emitting layer and a second electrode, which constitute a light emitting element, may be disposed on the planarization layer PLN. For example, as shown in FIG. 10, the first electrode 120 (or the anode electrode) may be disposed on the planarization layer PLN. The first electrode 120 may be electrically connected to the divided connection pattern DCP through a contact hole passing through the planarization layer PLN and the second passivation layer PAS2, which are interposed therebetween with the divided connection pattern DCP.

FIG. 11 is a cross-sectional view taken along line III-III′ shown in FIG. 6 according to another embodiment of the present disclosure. The divided connection pattern shown in FIG. 10 is modified in FIG. 11. Therefore, in the following description, the same reference numerals will be given to the other same elements except for the modified element, and their redundant description will be omitted or briefly described.

Referring to FIG. 11, the divided connection pattern DCP may be disposed on the first passivation layer PAS1. The divided connection pattern DCP may be disposed in the transmissive area TA. The divided connection pattern DCP may be formed of a transparent metal layer so as to improve light transmittance of the transmissive area TA. At least a portion of the pixel power line VDDL and the common power line VSSL, which are disposed in the non-transmissive area NTA, may be formed of the same material as that of the divided connection pattern DCP. For example, the pixel power line VDDL may include a first layer VDDLa made of a transparent metal layer and a second layer VDDLb stacked on the first layer VDDLa and made of an opaque metal layer. The divided connection pattern DCP may include a first layer DCPa made of a transparent metal layer. For example, the first layers VDDLa and DCPa of the pixel power line VDDL and the divided connection pattern DCP may be made of indium-tin oxide (ITO), but the embodiments of the present disclosure are not limited thereto. The second layer VDDLb of the pixel power line VDDL may be a single layer containing at least one of molybdenum (Mo), copper (Cu) or molytitanium (MoTi), or may be formed of a multi-layer containing at least two of them, but the embodiments of the present disclosure are not limited thereto. For example, the pixel power line VDDL and the divided connection pattern DCP are simultaneously formed through the same process and the second layer of the divided connection pattern DCP is removed by selective etching, whereby the divided connection pattern DCP made of only the transparent first layer DCPa may be implemented or realized.

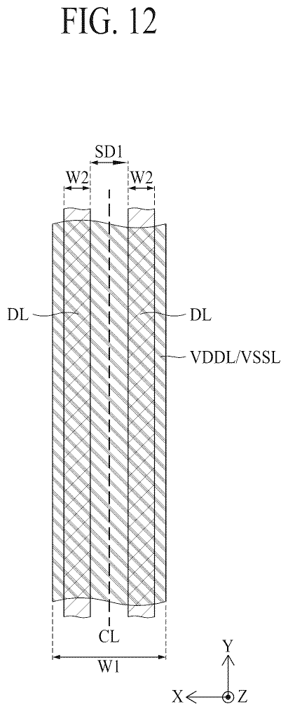

FIG. 12 is a plan view illustrating a power line and a data line according to one embodiment of the present disclosure.

Referring to FIG. 12, a pixel power line VDDL and a common power line VSSL according to one embodiment of the present disclosure may overlap at least a portion of a plurality of data lines DL. The pixel power line VDDL, the common power line VSSL and the plurality of data lines DL may be disposed in parallel in the first direction (or Y-axis direction).

The pixel power line VDDL and the common power line VSSL may have a width equal to or wider than that of the plurality of data lines DL. For example, the pixel power line VDDL and the common power line VSSL may be configured to have a first width W1, and each of the plurality of data lines DL may be configured to have a second width W2. The first width W1 may be equal to or wider than the second width W2. For example, the first width W1 may be wider than a multiple of the second width W2.

The plurality of data lines DL that overlap each of the pixel power line VDDL and the common power line VSSL may be spaced apart from each other in a width direction (or X-axis direction or the second direction) of the pixel power line VDDL and the common power line VSSL. A spaced distance SD1 between the plurality of data lines DL may be equal to or longer than a width W2 of each of the plurality of data lines DL. For example, the plurality of data lines DL may not overlap a central portion CL of the pixel power line VDDL and the common power line VSSL in the width direction (or X-axis direction or the second direction). The plurality of data lines DL may be disposed symmetrically with respect to the central portion CL of the pixel power line VDDL and the common power line VSSL in the width direction (or X-axis direction or the second direction).

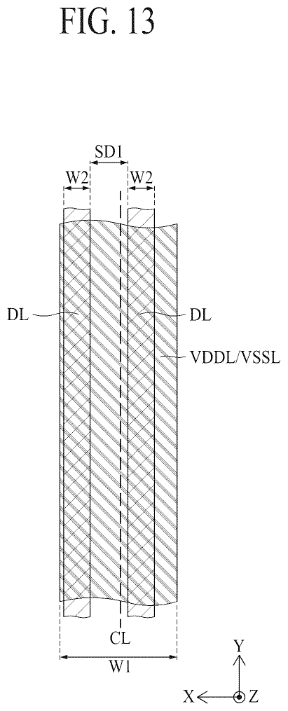

FIGS. 13 to 17 are plan views illustrating a power line and a data line according to another embodiment of the present disclosure. The power line and the data line, which are shown in FIG. 12, are modified in FIGS. 13 to 17. Therefore, in the following description, the same reference numerals will be given to the other same elements except for the modified element, and their redundant description will be omitted or briefly described.

Referring to FIG. 13, a pixel power line VDDL and a common power line VSSL according to another embodiment of the present disclosure may overlap at least a portion of a plurality of data lines DL.

The plurality of data lines DL may be disposed to be adjacent to one edge of the pixel power line VDDL and the common power line VSSL in the width direction (or X-axis direction or the second direction). The plurality of data lines DL may not overlap the central portion CL of the pixel power line VDDL and the common power line VSSL in the width direction (or X-axis direction or the second direction). For example, the plurality of data lines DL may be disposed to be adjacent to a left edge of the pixel power line VDDL and the common power line VSSL in the width direction (or X-axis direction or the second direction). Alternatively, the plurality of data lines DL may be disposed to be adjacent to a right edge of the pixel power line VDDL and the common power line VSSL in the width direction (or X-axis direction or the second direction).

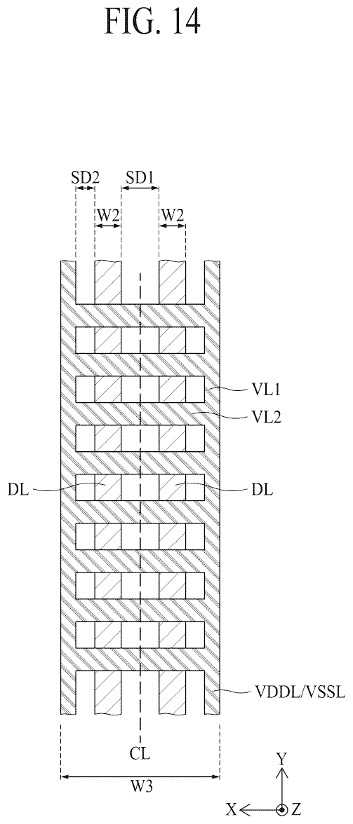

Referring to FIG. 14, a pixel power line VDDL and a common power line VSSL according to another embodiment of the present disclosure may overlap at least a portion of a plurality of data lines DL.

The pixel power line VDDL and the common power line VSSL may be configured to have a mesh pattern including a grid. For example, the pixel power line VDDL and the common power line VSSL may be configured in a ladder-shaped mesh pattern.

The pixel power line VDDL and the common power line VSSL may include a first mesh line VL1 extended in a first direction (or Y-axis direction) and a second mesh line VL2 extended in a second direction (or X-axis direction) crossing the first direction. The first mesh line VL1 may include a pair of lines parallel with each other in the first direction (or Y-axis direction) and spaced apart from each other in the second direction (or X-axis direction) with the plurality of data lines DL interposed therebetween. The second mesh line VL2 may be disposed between the pair of first mesh lines VL1, and may be formed of a plurality of lines spaced apart from each other in the first direction.

The pixel power line VDDL and the common power line VSSL may be configured to have a third width W3, and each of the plurality of data lines DL may be configured to have a second width W2. The third width W3 may be the same as or wider than the second width W2. For example, the third width W3 may be wider than a multiple of the second width W2.

The plurality of data lines DL that overlap each of the pixel power line VDDL and the common power line VSSL may be spaced apart from each other in the width direction (or X-axis direction or the second direction) of the pixel power line VDDL and the common power line VSSL. A spaced distance SD1 between the plurality of data lines DL may be equal to or longer than the width W2 of each of the plurality of data lines DL. For example, the plurality of data lines DL may not overlap the central portion CL of the pixel power line VDDL and the common power line VSSL in the width direction (or X-axis direction or the second direction), and may be disposed symmetrically with respect to the central portion CL. For example, the plurality of data lines DL may not overlap the first mesh line VL1 of the pixel power line VDDL1 and the common power line VSSL. The plurality of data lines DL may be spaced apart from the first mesh line VL1. A spaced distance SD2 between the plurality of data lines DL and the first mesh line VL1 may be equal to or shorter than the width W2 of each of the plurality of data lines DL.

Since the pixel power line VDDL and the common power line VSSL according to another embodiment of the present disclosure are configured to have a mesh pattern, an area in which the pixel power line VDDL, the common power line VSSL and the plurality of data lines DL overlap one another may be reduced, whereby the influence of parasitic capacitance may be reduced. In addition, since the pixel power line VDDL and the common power line VSSL according to another embodiment of the present disclosure are configured to have a mesh pattern, when a contact defect occurs between the pixel power line VDDL and the common power line VSSL and the plurality of data lines DL, a repair structure capable of repairing a contact defect by cutting the first mesh line VL1 and/or the second mesh line VL2 around the data line DL having a contact defect may be provided.

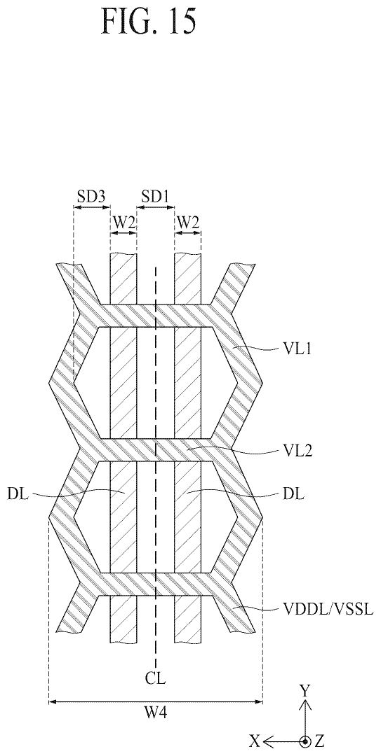

Referring to FIG. 15, a pixel power line VDDL and a common power line VSSL according to another embodiment of the present disclosure may overlap at least a portion of the plurality of data lines DL.

The pixel power line VDDL and the common power line VSSL may be configured to have a mesh pattern including a polygonal shape. For example, the pixel power line VDDL and the common power line VSSL may be configured in a hexagonal mesh pattern.

The pixel power line VDDL and the common power line VSSL may include a first mesh line VL1 extended in a first direction (or Y-axis direction) and a second mesh line VL2 extended in a second direction (or X-axis direction) crossing the first direction. The first mesh line VL1 may be extended in a sawtooth shape in the first direction (or Y-axis direction), and may include a pair of lines spaced apart from each other in the second direction (or X-axis direction) with the plurality of data lines DL interposed therebetween. The second mesh line VL2 may include a plurality of lines disposed between the pair of first mesh lines VL1 and spaced apart from each other in the first direction.

The pixel power line VDDL and the common power line VSSL may be configured to have a fourth width W4, and each of the plurality of data lines DL may be configured to have a second width W2. The fourth width W4 may be the same as or wider than the second width W2. For example, the fourth width W4 may be wider than a multiple of the second width W2.

The plurality of data lines DL do not overlap the central portion CL of the pixel power line VDDL and the common power line VSSL in the width direction (or X-axis direction or the second direction), and may be disposed symmetrically with respect to the central portion CL. For example, the plurality of data lines DL may not overlap the first mesh line VL1 of the pixel power line VDDL and the common power line VSSL. The plurality of data lines DL may be spaced apart from the first mesh line VL1. A maximum spaced distance SD3 between the plurality of data lines DL and the first mesh line VL1 may be equal to or longer than the width W2 of each of the plurality of data lines DL.

Since the pixel power line VDDL and the common power line VSSL according to another embodiment of the present disclosure are configured to have a mesh pattern, an area in which the pixel power line VDDL, the common power line VSSL and the plurality of data lines DL overlap one another may be reduced, whereby the influence of parasitic capacitance may be reduced. In addition, since the pixel power line VDDL and the common power line VSSL according to another embodiment of the present disclosure are configured to have a mesh pattern, when a contact defect occurs between the pixel power line VDDL and the common power line VSSL and the plurality of data lines DL, a repair structure capable of repairing a contact defect by cutting the first mesh line VL1 and/or the second mesh line VL2 around the data line DL having a contact defect may be provided.

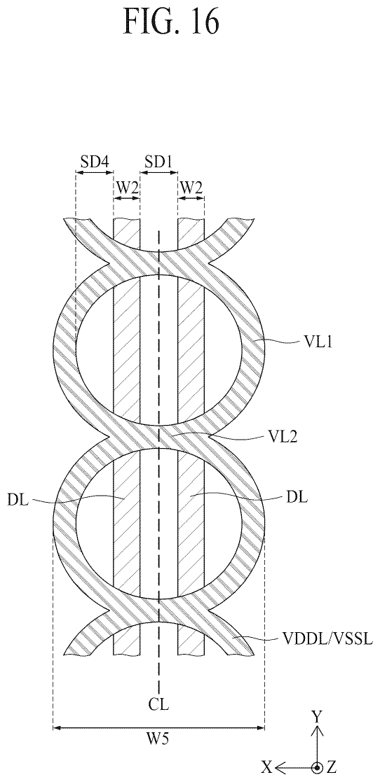

Referring to FIG. 16, a pixel power line VDDL and a common power line VSSL according to another embodiment of the present disclosure may overlap at least a portion of the plurality of data lines DL.

The pixel power line VDDL and the common power line VSSL may be configured to have a mesh pattern including a circular shape. For example, the pixel power line VDDL and the common power line VSSL may be configured in a circular mesh pattern.

The pixel power line VDDL and the common power line VSSL may include a partial circular first mesh line VL1 extended in a first direction (or Y-axis direction) and a partial circular second mesh line VL2 extended in a second direction (or X-axis direction) crossing the first direction. The first mesh line VL1 and the second mesh line VL2 may be formed of a generally circular line. The first mesh line VL1 and the second mesh line VL2 may be formed of circular lines repeated while overlapping each other in the first direction (or Y-axis direction).

The pixel power line VDDL and the common power line VSSL may be configured to have a fifth width W5, and each of the plurality of data lines DL may be configured to have a second width W2. The fifth width W5 may be the same as or wider than the second width W2. For example, the fifth width W5 may be wider than a multiple of the second width W2.

The plurality of data lines DL do not overlap the central portion CL of the pixel power line VDDL and the common power line VSSL in the width direction (or X-axis direction or the second direction), and may be disposed symmetrically with respect to the central portion CL. For example, the plurality of data lines DL may not overlap the first mesh line VL1 of the pixel power line VDDL and the common power line VSSL. The plurality of data lines DL may be spaced apart from the first mesh line VL1. A maximum spaced distance SD4 between the plurality of data lines DL and the first mesh line VL1 may be equal to or longer than the width W2 of each of the plurality of data lines DL.

Since the pixel power line VDDL and the common power line VSSL according to another embodiment of the present disclosure are configured to have a mesh pattern, an area in which the pixel power line VDDL, the common power line VSSL and the plurality of data lines DL overlap one another may be reduced, whereby the influence of parasitic capacitance may be reduced. In addition, since the pixel power line VDDL and the common power line VSSL according to another embodiment of the present disclosure are configured to have a mesh pattern, when a contact defect occurs between the pixel power line VDDL and the common power line VSSL and the plurality of data lines DL, a repair structure capable of repairing a contact defect by cutting the first mesh line VL1 and/or the second mesh line VL2 around the data line DL having a contact defect may be provided.

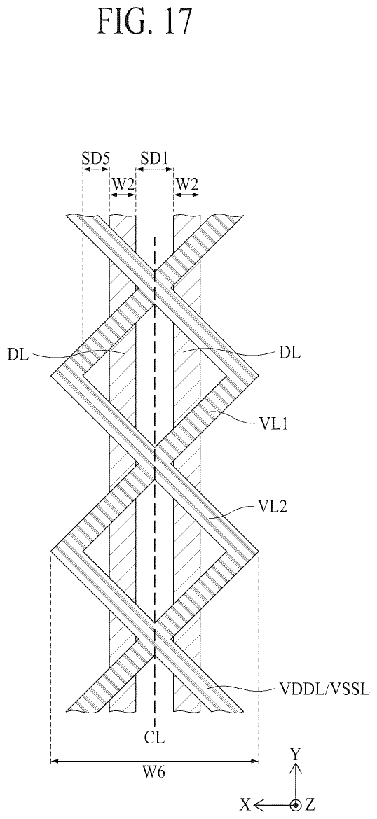

Referring to FIG. 17, a pixel power line VDDL and a common power line VSSL according to another embodiment of the present disclosure may overlap at least a portion of the plurality of data lines DL.

The pixel power line VDDL and the common power line VSSL may be configured to have a mesh pattern including a polygonal shape. For example, the pixel power line VDDL and the common power line VSSL may be configured in a rectangular mesh pattern. For example, the pixel power line VDDL and the common power line VSSL may be configured in a rhombus-shaped mesh pattern.

The pixel power line VDDL and the common power line VSSL may include a first mesh line VL1 extended in a diagonal direction between the first direction (or Y-axis direction) and the second direction (or X-axis direction) and a second mesh line VL2 extended in another diagonal direction crossing the diagonal direction of the first mesh line VL1. The first mesh line VL1 and the second mesh line VL2 may be configured to cross each other.

The pixel power line VDDL and the common power line VSSL may be configured to have a fifth width W5, and each of the plurality of data lines DL may be configured to have a second width W2. The fifth width W5 may be the same as or wider than the second width W2. For example, the fifth width W5 may be wider than a multiple of the second width W2.

The plurality of data lines DL may not overlap the central portion CL of the pixel power line VDDL and the common power line VSSL in the width direction (or X-axis direction or the second direction), and may be disposed symmetrically with respect to the central portion CL. For example, the plurality of data lines DL, and the pixel power line VDDL and the common power line VSSL may be spaced apart from one another at an outer crossing point at which the first mesh line VL1 and the second mesh line VL2 are connected to each other. A spaced distance SD4 between crossing points of the plurality of data lines DL and the first and second mesh lines VL1 and VL2 may be equal to or shorter than the width W2 of each of the plurality of data lines DL.

Since the pixel power line VDDL and the common power line VSSL according to another embodiment of the present disclosure are configured to have a mesh pattern, an area in which the pixel power line VDDL, the common power line VSSL and the plurality of data lines DL overlap one another may be reduced, whereby the influence of parasitic capacitance may be reduced. In addition, since the pixel power line VDDL and the common power line VSSL according to another embodiment of the present disclosure are configured to have a mesh pattern, when a contact defect occurs between the pixel power line VDDL and the common power line VSSL and the plurality of data lines DL, a repair structure capable of repairing a contact defect by cutting the first mesh line VL1 and/or the second mesh line VL2 around the data line DL having a contact defect may be provided.

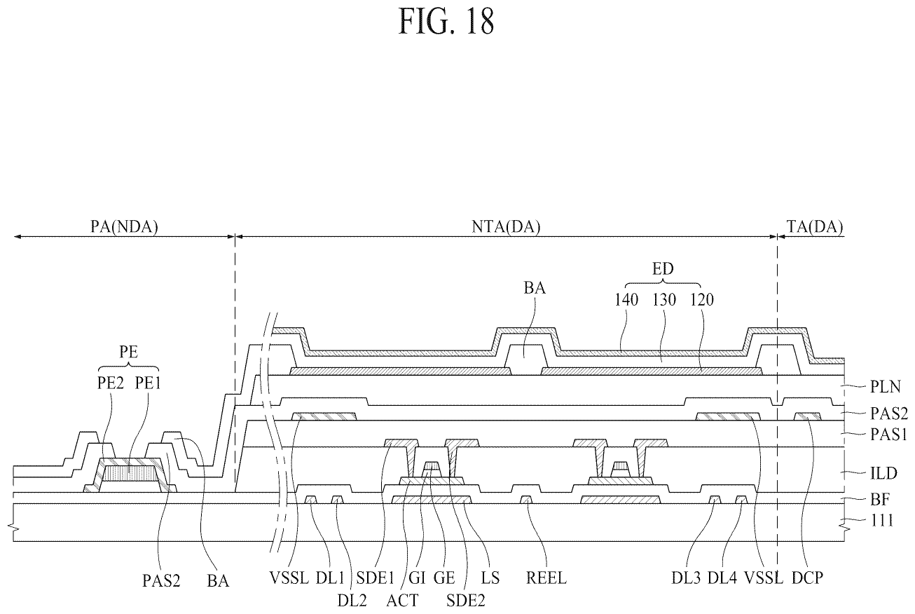

FIG. 18 is a cross-sectional view illustrating a transparent display apparatus according to one embodiment of the present disclosure.

Referring to FIG. 18 in conjunction with FIGS. 1 to 3, the transparent display panel 110 according to one embodiment of the present disclosure may include a display area DA and a pad area PA on a substrate 111. For example, the pad area PA may be a portion of the non-display area NDA near the display area DA.

The transparent display panel 110 according to one embodiment of the present disclosure may include a substrate 111, a light shielding layer LS, a plurality of data lines DL1, DL2, DL3 and DL4, a reference line REFL, a pad electrode PE, a buffer layer BF, an active layer ACT of a thin film transistor, a gate insulating layer GI, a gate electrode GE, a first source/drain electrode SDE1, a second source/drain electrode SED2, an interlayer insulating layer ILD, a first passivation layer PAS1, a pixel power line VDDL, a common power line VSSL, a divided connection pattern DCP, a second passivation layer PAS2, a planarization layer PLN, a light emitting element ED, a bank layer BA and the like.

The substrate 111 is a base substrate, and may be made of a glass material or a plastic material. For example, the substrate 111 is formed of a plastic material such as polyimide (PI), polyethylene terephthalate (PET), polyethylene naphthalate (PEN) and polycarbonate (PC), and thus may have flexible characteristics, but the embodiments of the present disclosure are not limited thereto.

A first signal line SL1 and a second signal line SL2, a circuit element that includes thin film transistors DTR, TR1 and TR2 and a storage capacitor Cst may be formed on the substrate 111 for each of a plurality of subpixels SP1, SP2, SP3 and SP4. For example, the first signal line SL1 may include a pixel power line VDDL (or a first power line), a common power line VSSL (or a second power line), a reference line REFL and data lines DL1, DL2, DL3 and DL4. The second signal line SL2 may include a scan line SCANL (or a gate line). The thin film transistors DTR, TR1 and TR2 may include a driving transistor DTR, a first switching transistor TR1 and a second switching transistor TR2, but the embodiments of the present disclosure are not limited thereto.

A light shielding layer LS, a plurality of data lines DL1, DL2, DL3 and DL4 and a reference line REFL may be disposed in the display area DA on the substrate 111. The light shielding layer LS may overlap at least a portion of the thin film transistors DTR, TR1 and TR2. For example, the light shielding layer LS may overlap the active layer ACT of the thin film transistor. The light shielding layer LS may be formed of a single layer or multi-layer made of any one of molybdenum (Mo), aluminum (Al), chromium (Cr), gold (Au), titanium (Ti), nickel (Ni), neodymium (Nd) and copper (Cu) or their alloy. For example, the light shielding layer LS, the plurality of data lines DL1, DL2, DL3 and DL4 and the reference line REFL on the substrate 111 may be formed of the same material on the same layer. For example, the light shielding layer LS, the plurality of data lines DL1, DL2, DL3 and DL4 and the reference line REFL may be simultaneously formed through the same process, but the embodiments of the present disclosure are not limited thereto. For example, the reference line REFL may be disposed between the adjacent subpixels SP1, SP2, SP3 and SP4, and the first and second data lines DL1 and DL2 of the data lines DL1, DL2, DL3 and DL4 may be disposed at one side of the subpixels SP1, SP2, SP3 and SP4 and the third and fourth data lines DL3 and DL4 of the data lines DL1, DL2, DL3 and DL4 may be disposed at the other side of the subpixels SP1, SP2, SP3 and SP4.

A buffer layer BF may be disposed on the substrate 111 to cover the light shielding layer LS, the plurality of data lines DL1, DL2, DL3 and DL4 and the reference line REFL. The buffer layer BF is to protect the thin film transistor from moisture permeated through the substrate 111 that may be vulnerable to moisture permeation, and may be formed of a single layer or multi-layer containing an inorganic insulating material such as silicon oxide (SiOₓ), silicon nitride (SiNₓ) and aluminum oxide (Al₂O₃).

The buffer layer BF may be provided on an entire upper surface of the substrate 111 or a portion of the upper surface of the substrate 111 in order to block ions or impurities diffused from the substrate 111 and to block moisture permeated into the light emitting element ED through the substrate 111. For example, the buffer layer BF may be formed on the entire display area DA of the substrate 111, and may not be formed in the non-display area NDA of the substrate 111, but the embodiments of the present disclosure are not limited thereto.

At least one insulating layer, a thin film transistor and at least one signal line may be disposed on the buffer layer BF. For example, the thin film transistor may be disposed on the buffer layer BF. The thin film transistor may include an active layer ACT disposed on the buffer layer BF, a gate electrode GE, a first source/drain electrode SDE1 and a second source/drain electrode SDE2.

A gate insulating layer GI may be disposed between the active layer ACT and the gate electrode GE. The gate insulating layer GI may be patterned only in an area where the gate electrode GE is disposed, or may be formed to cover the active layer ACT, but the embodiments of the present disclosure are not limited thereto.

The interlayer insulating layer ILD may be disposed between the gate electrode GE and the first source/drain electrode SDE1 and the second source/drain electrode SDE2. The first source/drain electrode SDE1 and the second source/drain electrode SDE2 of the thin film transistor may be electrically connected to the active layer ACT through a contact hole passing through the interlayer insulating layer ILD.

The active layer ACT may be formed of a silicon-based semiconductor material or an oxide-based semiconductor material. The gate electrode GE, the first source/drain electrode SDE1 and the second source/drain electrode SDE2 may be formed of a single layer or multi-layer made of any one of molybdenum (Mo), aluminum (Al), chromium (Cr), gold (Au), titanium (Ti), nickel (Ni), neodymium (Nd) and copper (Cu) or their alloy, but the embodiments of the present disclosure are not limited thereto.

The gate insulating layer GI and the interlayer insulating layer ILD may be formed of a single layer or multi-layer containing an inorganic insulating material such as silicon oxide (SiOₓ), silicon nitride (SiNₓ) and aluminum oxide (Al₂O₃), but the embodiments of the present disclosure are not limited thereto.

A first passivation layer PAS1 may be disposed on the interlayer insulating layer ILD on which the first source/drain electrode SDE1 and the second source/drain electrode SDE2 of the thin film transistor are disposed. A second passivation layer PAS2 may be disposed on the first passivation layer PAS1. The first passivation layer PAS1 and the second passivation layer PAS2 may be formed of a single layer or multi-layer containing an inorganic insulating material such as silicon oxide (SiOₓ), silicon nitride (SiNₓ) and aluminum oxide (Al₂O₃).

The pixel power line VDDL (or the first power line) and the common power line VSSL (or the second power line) may be disposed on the first passivation layer PAS1 of the display area DA. The pixel power line VDDL and the common power line VSSL may be disposed between the first passivation layer PAS1 and the second passivation layer PAS2. For example, the pixel power line VDDL and the common power line VSSL may be disposed in the non-transmissive area NTA of the display area DA. For example, the pixel power line VDDL may be disposed to overlap the first and second data lines DL1 and DL2, and the common power line VSSL may be disposed to overlap the third and fourth data lines DL3 and DL4.

On the first passivation layer PAS1 of the display area DA, a divided connection pattern DCP made of the same material as that of the pixel power line VDDL and the common power line VSSL may be disposed on the same layer as the pixel power line VDDL and the common power line VSSL. For example, the divided connection pattern DCP may be disposed in the transmissive area TA of the display area DA.

The pixel power line VDDL, the common power line VSSL and the divided connection pattern DCP may be made of a single layer containing at least one of molybdenum (Mo), copper (Cu), molytitanium (MoTi) or indium tin oxide (ITO) or a multi-layer containing at least two of them, but the embodiments of the present disclosure are not limited thereto.

A planarization layer PLN for planarizing a step difference caused by a thin film transistor and a plurality of signal lines may be disposed on the second passivation layer PAS2. The planarization layer PLN may be formed of an organic material such as an acrylic resin, an epoxy resin, a phenolic resin, a polyamide resin and a polyimide resin.

Light emitting elements ED, which include a first electrode 120, an organic light emitting layer 130 and a second electrode 140, and a bank layer BA may be disposed on the planarization layer PLN. For example, the first electrode 120 may be disposed for each of subpixels SP1, SP2, SP3 and SP4, and may be disposed in the non-transmissive area NTA. The first electrode 120 may be formed of a metal material having high reflectance, such as a stacked structure (Ti/Al/Ti) of aluminum and titanium, a stacked structure (ITO/AI/ITO) of aluminum and ITO, Ag alloy, a stacked structure (ITO/Ag alloy/ITO) of Ag alloy and ITO, MoTi alloy, and a stacked structure (ITO/MoTi alloy/ITO) of MoTi alloy and ITO. The Ag alloy may be an alloy of silver (Ag), palladium (Pd), copper (Cu) and the like. The MoTi alloy may be an alloy of molybdenum (Mo) and titanium (Ti). The first electrode 120 may be an anode electrode of the light emitting element ED. An organic light emitting layer 130 and a second electrode 140 may be disposed on the first electrode 120. The first electrode 120, the organic light emitting layer 130 and the second electrode 140 may constitute the light emitting element ED.

The bank layer BA may be disposed on the planarization layer PLN. The bank layer BA may be disposed between the first electrodes 120. For example, the bank layer BA may be configured to cover an edge of each of the first electrodes 120 and expose a portion of each of the first electrodes 120. The bank layer BA may be formed of an organic layer such as an acrylic resin, an epoxy resin, a phenolic resin, a polyamide resin and a polyimide resin.

The organic light emitting layer 130 may be disposed on the first electrode 120. The organic light emitting layer 130 may include a hole transporting layer, an emission material layer and an electron transporting layer. For example, when a voltage is applied to the first electrode 120 and the second electrode 140, holes and electrons move to the organic light emitting layer 130 through the hole transporting layer and the electron transporting layer, respectively, and may be combined with each other in the light emitting layer to emit light.

The second electrode 140 may be a common layer commonly formed in the subpixels SP1, SP2, SP3 and SP4 to apply the same voltage. The second electrode 140 may be formed of a transparent conductive material (TCO) such as ITO or IZO capable of transmitting light or a semi-transmissive conductive material such as magnesium (Mg), silver (Ag) or an alloy of magnesium (Mg) and silver (Ag). When the second electrode 140 is formed of a semi-transmissive metal material, light emission efficiency may be increased by a micro cavity. The second electrode 140 may be a cathode electrode of the light emitting element ED.

The non-display area NDA on the substrate 111 may include a pad area PA. A pad electrode PE may be disposed in the pad area PA on the substrate 111. The pad electrode PE may include a first pad electrode PE1 and a second pad electrode PE2. At least a portion of the pad electrode PE may be formed of the same material as that of the pixel power line VDDL, the common power line VSSL and the divided connection pattern DCP disposed in the display area DA on the substrate 111.

The first pad electrode PE1 made of the same material as that of the gate insulating layer GI and the gate electrode GE may be disposed in the pad area PA on the substrate 111. For example, the first pad electrode PE1 may be formed of the same material as that of the gate insulating layer GI and the gate electrode GE of the thin film transistor on a layer different from the gate insulating layer GI and the gate electrode GE.

The second pad electrode PE2 may be disposed on the first pad electrode PE1. For example, the second pad electrode PE2 may be configured to cover the first pad electrode PE1 and the gate insulating layer GI. The second pad electrode PE2 may be formed of the same material as that of at least a portion of the pixel power line VDDL, the common power line VSSL and the divided connection pattern DCP. For example, the second pad electrode PE2 may be formed of the same material as that of the pixel power line VDDL, the common power line VSSL and the divided connection pattern DCP on a layer different from the pixel power line VDDL, the common power line VSSL and the divided connection pattern DCP.

The second passivation layer PAS2 and the bank layer BA may be disposed on the second pad electrode PE2. For example, the second passivation layer PAS2 and the bank layer BA may be configured to cover an edge of the second pad electrode PE2.

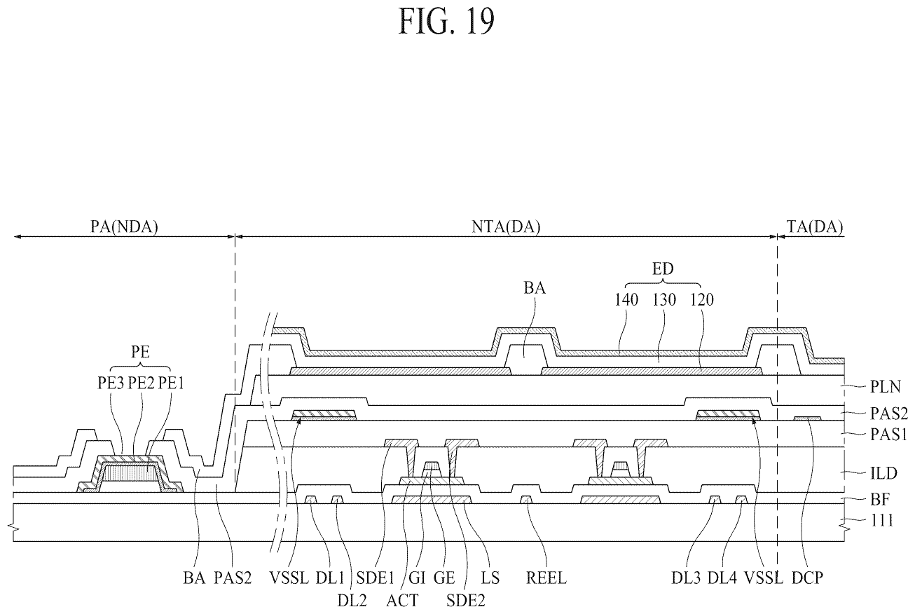

FIG. 19 is a cross-sectional view illustrating a transparent display apparatus according to another embodiment of the present disclosure. The pixel power line VDDL, the common power line VSSL, the divided connection pattern DCP and the pad electrode PE in the transparent display panel 110 described with reference to FIG. 18 are modified in FIG. 19. Therefore, in the following description, the same reference numerals will be given to the other same elements except for the modified elements, and their redundant description will be omitted or briefly described.

Referring to FIG. 19, the pixel power line VDDL and the common power line VSSL according to another embodiment of the present disclosure may include, as shown in FIG. 11, a first layer made of a transparent metal layer and a second layer stacked on the first layer and made of an opaque metal layer. The pixel power line VDDL and the common power line VSSL may be disposed in the non-transmissive area NTA of the display area DA. At least a portion of the pixel power line VDDL and the common power line VSSL may be formed of the same material as that of the divided connection pattern DCP. The divided connection pattern DCP may be disposed in the transmissive area TA of the display area DA.

The divided connection pattern DCP may include a first layer made of a transparent metal layer. For example, the first layer of each of the pixel power line VDDL, the common power line VSSL and the divided connection pattern DCP may be formed of indium tin oxide (ITO), but the embodiments of the present disclosure are not limited thereto. The second layer of the pixel power line VDDL and the common power line VSSL may be a single layer containing at least one of molybdenum (Mo), copper (Cu) or molytitanium (MoTi), or may be formed of a multi-layer containing at least two of them, but the embodiments of the present disclosure are not limited thereto. For example, the pixel power line VDDL, the common power line VSSL and the divided connection pattern DCP are simultaneously formed through the same process, and the second layer of the divided connection pattern DCP is removed by selective etching, whereby the divided connection pattern DCP made of only the transparent first layer may be implemented or realized.

The pad electrode PE may be disposed in the pad area PA on the substrate 111. The pad electrode PE may include a first pad electrode PE1, a second pad electrode PE2 and a third pad electrode PE3. At least a portion of the pad electrode PE may be formed of the same material as that of the pixel power line VDDL, the common power line VSSL and the divided connection pattern DCP, which are disposed in the display area DA on the substrate 111.

The first pad electrode PE1 made of the same material as that of the gate insulating layer GI and the gate electrode GE may be disposed in the pad area PA on the substrate 111. For example, the first pad electrode PE1 may be formed of the same material as that of the gate insulating layer GI and the gate electrode GE of the thin film transistor on a layer different from the gate insulating layer GI and the gate electrode GE.

The second pad electrode PE2 and the third pad electrode PE3 may be disposed on the first pad electrode PE1. For example, the second pad electrode PE2 and the third pad electrode PE3 may be configured to cover the first pad electrode PE1 and the gate insulating layer GI.

The second pad electrode PE2 may be formed of the same material as that of at least a portion of the pixel power line VDDL, the common power line VSSL and the divided connection pattern DCP. For example, the second pad electrode PE2 may be formed of the same material as that of the transparent first layer of the pixel power line VDDL, the common power line VSSL and the divided connection pattern DCP. For example, the second pad electrode PE2 may be formed of the same material as that of the transparent first layer on a layer different from the transparent first layer of the pixel power line VDDL, the common power line VSSL and the divided connection pattern DCP.

The third pad electrode PE3 may be formed of the same material as that of at least a portion of the pixel power line VDDL and the common power line VSSL. For example, the third pad electrode PE3 may be formed of the same material as that of the opaque second layer of the pixel power line VDDL and the common power line VSSL. For example, the third pad electrode PE3 may be formed of the same material as that of the opaque second layer on a layer different from the opaque second layer of the pixel power line VDDL and the common power line VSSL.

The second passivation layer PAS2 and the bank layer BA may be disposed on the third pad electrode PE3. For example, the second passivation layer PAS2 and the bank layer BA may be configured to cover an edge of the third pad electrode PE3.

A transparent display apparatus according to one or more embodiments of the present disclosure will be described below.

A transparent display apparatus according to one or more embodiments of the present disclosure may include a substrate including a non-transmissive area and a transmissive area, the non-transmissive area comprising a light emission area in which a light emitting element is disposed, a plurality of data lines in the non-transmissive area on the substrate, the plurality of data lines extending in a first direction, at least one gate line on the substrate, the at least one gate line extending across the non-transmissive area and the transmissive area in a second direction that intersects the first direction, and at least one power line on the substrate, the at least one power line overlapping with at least a portion of the plurality of data lines with at least one insulating layer interposed therebetween on the substrate.

According to one or more embodiments of the present disclosure, the at least one power line may be in parallel with the plurality of data lines in the first direction.

According to one or more embodiments of the present disclosure, the at least one power line may have a width equal to or wider than that of the plurality of data lines.

According to one or more embodiments of the present disclosure, the plurality of data lines may overlap the at least one power line.

According to one or more embodiments of the present disclosure, the plurality of data lines may be spaced apart from each other in a width direction of the at least one power line.

According to one or more embodiments of the present disclosure, a spaced distance between the plurality of data lines may be equal to or longer than a width of each of the plurality of data lines.

According to one or more embodiments of the present disclosure, the plurality of data lines may be non-overlapping with a center portion of the at least one power line in a width direction.

According to one or more embodiments of the present disclosure, the plurality of data lines may be symmetric with respect to a center portion of the at least one power line in a width direction.

According to one or more embodiments of the present disclosure, the plurality of data lines may be adjacent to one edge of the at least one power line in a width direction.

According to one or more embodiments of the present disclosure, the at least one power line may be spaced apart from the plurality of data lines with the at least one insulating layer interposed therebetween.

According to one or more embodiments of the present disclosure, the at least one power line may have a thickness equal to or different from that of the plurality of data lines.

According to one or more embodiments of the present disclosure, the at least one insulating layer may have a thickness equal to or greater than that of the plurality of data lines.

According to one or more embodiments of the present disclosure, the at least one insulating layer may have a thickness equal to or greater than a multiple of a thickness of the plurality of data lines.

According to one or more embodiments of the present disclosure, the at least one insulating layer may include at least one of an inorganic insulating material or an organic insulating material.

According to one or more embodiments of the present disclosure, the at least one power line may have a mesh pattern that includes a polygon, a circle or a grid.

According to one or more embodiments of the present disclosure, the at least one power line may be a single layer including at least one of molybdenum (Mo), copper (Cu), molytitanium (MoTi) or indium-tin oxide (ITO) or a multi-layer including at least two of Mo, Cu, MoTi, or ITO.

According to one or more embodiments of the present disclosure, the light emitting element may include a first divided electrode and a second divided electrode spaced apart from each other, and a divided connection pattern electrically connecting the first divided electrode with the second divided electrode.

According to one or more embodiments of the present disclosure, the at least one power line may be on a same layer as the divided connection pattern.

According to one or more embodiments of the present disclosure, at least a portion of the at least one power line may comprises a same material as the divided connection pattern.

According to one or more embodiments of the present disclosure, the divided connection pattern may be in the transmissive area on the substrate.

According to one or more embodiments of the present disclosure, the transparent display apparatus may further comprise a pad electrode in a pad area on the substrate, and at least a portion of the pad electrode may comprises a same material as the at least one power line.

According to one or more embodiments of the present disclosure, the at least one power line may include a first power line and a second power line, and the transparent display apparatus may further include a first subpixel, a second subpixel, a third subpixel, and a fourth subpixel between the first power line and the second power line, and the plurality of data lines may include a first data line, a second data line, a third data line, and a fourth data line connected to the first subpixel, the second subpixel, the third subpixel, and the fourth subpixel, respectively.

According to one or more embodiments of the present disclosure, the first data line and the second data line may overlap the first power line, and the third data line and the fourth data line may overlap the second power line.

According to one or more embodiments of the present disclosure, the first subpixel and the second subpixel may be adjacent to the first power line, and the third subpixel and the fourth subpixel may be adjacent to the second power line.

According to one or more embodiments of the present disclosure, the at least one gate line may be disposed between the first subpixel and the second subpixel and between the third subpixel and the fourth subpixel.

A transparent display apparatus according to one or more embodiments of the present disclosure may include a substrate including a display area and a non-display area around the display area, the displayer area may include a plurality of light emission areas arranged in a first direction, a plurality of data lines in the plurality of light emission areas on the substrate, the plurality of data lines extending in the first direction, a plurality of gate lines on the substrate, the plurality of gate lines extending in a second direction that intersects the first direction, and a power line on the substrate, the power line overlapping with at least a portion of the plurality of data lines with an insulating layer interposed therebetween.

According to one or more embodiments of the present disclosure, the power line may be above the plurality of data lines.

According to one or more embodiments of the present disclosure, the power line may have a width equal to or wider than that of the plurality of data lines.

It will be apparent to those skilled in the art that various modifications and variations may be made in the apparatus of the present disclosure without departing from the scope of the disclosure. Thus, it is intended that the present disclosure cover the modifications and variations of this disclosure provided that within the scope of the claims and their equivalents.

What is claimed is:

1. A transparent display apparatus comprising:
a substrate including a non-transmissive area and a transmissive area, the non-transmissive area comprising a light emission area in which a light emitting element is disposed;
a plurality of data lines in the non-transmissive area on the substrate, the plurality of data lines extending in a first direction;
at least one gate line on the substrate, the at least one gate line extending across the non-transmissive area and the transmissive area in a second direction that intersects the first direction; and
at least one power line on the substrate, the at least one power line overlapping with at least a portion of the plurality of data lines with at least one insulating layer interposed therebetween on the substrate.

2. The transparent display apparatus of claim 1, wherein the at least one power line is in parallel with the plurality of data lines in the first direction.

3. The transparent display apparatus of claim 1, wherein the at least one power line has a width equal to or wider than that of the plurality of data lines.

4. The transparent display apparatus of claim 1, wherein the plurality of data lines overlap the at least one power line.

5. The transparent display apparatus of claim 1, wherein the plurality of data lines are spaced apart from each other in a width direction of the at least one power line.

6. The transparent display apparatus of claim 5, wherein a spaced distance between the plurality of data lines is equal to or longer than a width of each of the plurality of data lines.

7. The transparent display apparatus of claim 1, wherein the plurality of data lines are non-overlapping with a center portion of the at least one power line in a width direction.

8. The transparent display apparatus of claim 1, wherein the plurality of data lines are symmetric with respect to a center portion of the at least one power line in a width direction.

9. The transparent display apparatus of claim 1, wherein the plurality of data lines are adjacent to one edge of the at least one power line in a width direction.

10. The transparent display apparatus of claim 1, wherein the at least one power line is spaced apart from the plurality of data lines with the at least one insulating layer interposed therebetween.

11. The transparent display apparatus of claim 1, wherein the at least one power line has a thickness equal to or different from that of the plurality of data lines.

12. The transparent display apparatus of claim 1, wherein the at least one insulating layer has a thickness equal to or greater than that of the plurality of data lines.

13. The transparent display apparatus of claim 12, wherein the at least one insulating layer has a thickness equal to or greater than a multiple of a thickness of the plurality of data lines.

14. The transparent display apparatus of claim 1, wherein the at least one insulating layer includes at least one of an inorganic insulating material or an organic insulating material.

15. The transparent display apparatus of claim 1, wherein the at least one power line has a mesh pattern that includes a polygon, a circle or a grid.

16. The transparent display apparatus of claim 1, wherein the at least one power line is a single layer including at least one of molybdenum (Mo), copper (Cu), molytitanium (MoTi) or indium-tin oxide (ITO), or a multi-layer including at least two of Mo, Cu, MoTi, or ITO.

17. The transparent display apparatus of claim 1, wherein the light emitting element includes:
a first divided electrode and a second divided electrode spaced apart from each other, and
a divided connection pattern electrically connecting the first divided electrode with the second divided electrode.

18. The transparent display apparatus of claim 17, wherein the at least one power line is on a same layer as the divided connection pattern.

19. The transparent display apparatus of claim 17, wherein at least a portion of the at least one power line comprises a same material as the divided connection pattern.

20. The transparent display apparatus of claim 17, wherein the divided connection pattern is in the transmissive area on the substrate.

21. The transparent display apparatus of claim 1, further comprising:
a pad electrode in a pad area on the substrate,
wherein at least a portion of the pad electrode comprises a same material as the at least one power line.

22. The transparent display apparatus of claim 1, wherein the at least one power line includes a first power line and a second power line; and
wherein the transparent display apparatus further includes a first subpixel, a second subpixel, a third subpixel, and a fourth subpixel between the first power line and the second power line, and
wherein the plurality of data lines include a first data line, a second data line, a third data line, and a fourth data line connected to the first subpixel, the second subpixel, the third subpixel, and the fourth subpixel, respectively.

23. The transparent display apparatus of claim 22, wherein the first data line and the second data line overlap the first power line, and the third data line and the fourth data line overlap the second power line.

24. The transparent display apparatus of claim 22, wherein the first subpixel and the second subpixel are adjacent to the first power line, and the third subpixel and the fourth subpixel are adjacent to the second power line.

25. The transparent display apparatus of claim 22, wherein the at least one gate line is between the first subpixel and the second subpixel and between the third subpixel and the fourth subpixel.

26. A transparent display apparatus comprising:
a substrate including a display area and a non-display area around the display area, wherein the displayer area comprises a plurality of light emission areas arranged in a first direction;
a plurality of data lines in the plurality of light emission areas on the substrate, the plurality of data lines extending in the first direction;
a plurality of gate lines on the substrate, the plurality of gate lines extending in a second direction that intersects the first direction; and
a power line on the substrate, the power line overlapping with at least a portion of the plurality of data lines with an insulating layer interposed therebetween.

27. The transparent display apparatus of claim 26, wherein the power line is above the plurality of data lines.

28. The transparent display apparatus of claim 1, wherein the power line has a width equal to or wider than that of the plurality of data lines.
